(19) United States
(12) Patent Application Publication
(10) Pub. No.: US 2011/0229743 A1
(43) Pub. Date: Sep. 22, 2011

(54) Power assembly

(76) Inventors: Yen-Wei Hsu, Taipei (TW); Whei-Chyou Wu, Fremont, CA (US)

(21) Appl. No.: 12/726,356

(22) Filed: Mar. 18, 2010

(51) Int. Cl. H01M 8/22; H01G 9/155; H01M 2/00; H01M 14/00; H01L 31/00

(52) U.S. Cl. 429/7; 361/502; 429/403; 429/10; 136/252

(57) ABSTRACT

The invention relates to an inventive electrochemical device and an inventive metal-air fuel cell and Zinc-air fuel cell are also revealed. The inventive electrochemical device can also be used as an amplifier, a power generator, a detector, a photoelectric conversion device or a charger.

### FIELD OF INVENTION

The invention relates to an inventive electrochemical device and an inventive metal-air fuel cell and Zinc-air fuel cell are also revealed. The inventive electrochemical device can also be used as an amplifier, a power generator, a detector, a photoelectric conversion device or a charger.

### BACKGROUND INFORMATION

### Introduction

There are many articles involved the topics of the nonlinear spectral analysis and reviewed as the following sections. The first one is the nonlinear dynamics and self-excited or self-oscillation systems. It provides a profound viewpoint of the nonlinear dynamical system behaviors, which are duality of second-order systems, self-excitation, orbital equivalence or structural stability, bifurcation, perturbation, harmonic balance, transient behaviors, frequency-amplitude and phase-amplitude relationships, jump phenomenon or singularity occurrence, frequency entrainment or synchronization, and so on. In particular, the self-induced current (voltage) or electricity generation appears if applying to the Liénard system.

### Dielectric Materials

Referring to [29, Chapter 4, 5, 8, 9], [18, Part One], [19, Chapter 1], [6, Chapter 14], the response of a material to an electric field can be used to advantage even when no charge is transferred. These effects are described by the dielectric properties of the material. Dielectric materials pons a large energy gap between the valence and conduction bands, thus the materials a high electrical resistivity. Because dielectric materials are used in the AC circuits, the dipoles must be able to switch directions, often in the high frequencies, where the dipoles are atoms or groups of atoms that have an unbalanced charge. Alignment of dipoles causes polarization which determines the behavior of the dielectric material. Electronic and ionic polarization occur easily even at the high frequencies. Some energy is lost as heat when a dielectric material polarized in the AC electric field. The fraction of the energy lost during each reversal is the dielectric loss. The energy losses are due to current leakage and dipoles friction (or change the direction). Losses due to the current leakage are low if the electrical resistivity is high, typically which behaves 10¹¹ Ohm·m or more. Dipole friction occurs when reorientation of the dipoles is difficult, as in complex organic molecules. The greatest loss occurs at frequencies where the dipoles almost, but not quite, can be reoriented. At lower frequencies, losses are low because the dipoles have time to move. At higher frequencies, losses are low because the dipoles do not move at all.

For a capacitor made from dielectric ceramics, referred to [18, Part One], [19, Chapter 1], [29, Page 253-255], its capacitance C, which is equivalent to one ideal capacitor Cᵢ and series resistance Rₛ in the FIG. 5, is function of frequency ω, equivalent series resistance Rₛ and loss tangent of dielectric materials tan δ where is defined as

$$tan δ = \frac{{ɛ}_{2}}{{ɛ}_{1}} \qquad ( 1 )$$

and the dielectric constant ∈ is a complex number as following

$$\begin{matrix}ɛ = ( {ɛ}_{1} + j {ɛ}_{2} ) \\ as & ( 2 ) \\ C = \frac{tan ( δ )}{{R}_{s} ω} & ( 3 )\end{matrix}$$

respectively. That is, if changing the Rₛ, tan(δ) for different materials or ω, the C becomes a variable capacitance. Also, the capacity is obtained by

$$\begin{matrix}C = ɛ \frac{E}{d} \\ = ( {ɛ}_{1} + j {ɛ}_{2} ) \frac{EA}{V}\end{matrix} \qquad ( 4 )$$

where the ∈, E, d, A and V are the dielectric constant, applied electric field, distance between two electrodes, effective area and volume of a capacitor respectively. In fact, from (4), the more effective area gets the more capacity. Combining (3) and (4), this serial resistance Rₛ becomes a function of the ω, E, A, V, δ as (5)

$$\begin{matrix}{R}_{s} = \frac{( 1 - j tan δ ) V cos δ}{ω EA tan δ} \\ = \frac{( 1 - j tan δ ) d sin δ}{ω E {ɛ}_{1}}\end{matrix} \qquad \begin{matrix}\begin{matrix}( 5 ) \\ \end{matrix} \\ ( 6 )\end{matrix}$$

also (6) is a function of the ∈₁, E, d, δ respectively. In fact we can obtain this resistance is perturbed by some additional factors, like as ω, E, δ, ∈ and so on, said ΔRₛ,

Rₛ=Rₛ⁰+ΔRₛ+O(1) (7)

where Rₛ⁰ is the zeroth order or constant resistance and the first order resistance ΔRₛ which varies with some specific factors, Δζ, dependent on the materials features, i.e.,

$$Δ {R}_{s} = \frac{Δ {R}_{s}}{Δ ζ} Δ ζ \qquad ( 8 )$$

Consequently, the perturbed resistance in (7) has the ΔRₛ>0, ΔRₛ=0, and ΔRₛ<0 different types of resistance and further discussion appears in the following paragraphs.

Referred to [33, Page 11], one ultracapacitor can be modeled as the RC network with three significant resistors R_{anode}, Rₛₑₚₐᵣₐₜₒᵣ or R_{membrane} and R_{cathode} respectively. The total equivalent resistance of the ultracapacitor is a constant resistor as

$${R}_{e} = {R}_{anode} + {R}_{separator} + {R}_{cathode} + {\sum }_{i}^{∞} ( {R}_{{p}_{i}} + {R}_{{n}_{i}} ) \qquad ( 9 )$$

where the term of summation in the (9) denotes a stochastic contact resistance between the electrolyte particles and two electrodes, and its totally variable equivalent capacitance is

$$Δ {C}_{e} = {\sum }_{i}^{∞} ( Δ {C}_{{p}_{i}} + Δ {C}_{{n}_{i}} ) \qquad ( 10 )$$

### Cauchy-Riemann Theorem

Referring to the [36], [10], [34] and [3], the complex variable analysis is a fundamental mathematical tool for the electrical circuit theory. In general, the impedance function consists of the real and imaginary parts. For each part of impedance functions, they are satisfied the Cauchy-Riemann Theorem. Let a complex function be

z(x,y)=F(x,y)+iG(x,y) (11)

where F (x, y) and G (x, y) are analytic functions in a domain D and the Cauchy-Riemann theorem is the first-order derivative of functions F (x, y) and G (x, y) with respect to x and y becomes

$$\begin{matrix}\frac{\partial F}{\partial x} = \frac{\partial G}{\partial y} \\ and & ( 12 ) \\ \frac{\partial F}{\partial y} = - \frac{\partial G}{\partial x} & ( 13 )\end{matrix}$$

Furthermore, taking the second-order derivative with respect to x and y, we can obtain two 2^{nd}-order partial differential equations as

$$\begin{matrix}\frac{{\partial }^{2} F}{\partial {x}^{2}} + \frac{{\partial }^{2} F}{\partial {y}^{2}} = 0 \\ and & ( 14 ) \\ \frac{{\partial }^{2} G}{\partial {x}^{2}} + \frac{{\partial }^{2} G}{\partial {y}^{2}} = 0 & ( 15 )\end{matrix}$$

respectively, also F (x, y) and G (x, y) are called the harmonic functions.

From the equation (11), the total derivative of the complex function z (x, y) is

$$dz ( x , y ) = ( \frac{\partial F}{\partial x} dx + \frac{\partial F}{\partial y} dy ) + i ( \frac{\partial G}{\partial x} dx + \frac{\partial G}{\partial y} dy ) \qquad ( 16 )$$

and substituting equations (12) and (13) into the form of (16), then the total derivative of the complex function (11) is dependent on the real function F (x, y) or in terms of the real-valued function F (x, y) (real part) only,

$$dz ( x , y ) = ( \frac{\partial F}{\partial x} dx + \frac{\partial F}{\partial y} dy ) + i ( \frac{\partial F}{\partial x} dy - \frac{\partial F}{\partial y} dx ) \qquad ( 17 )$$

and in terms of a real-valued function G (x, y) (imaginary part) only,

$$dz ( x , y ) = ( \frac{\partial G}{\partial y} dx - \frac{\partial G}{\partial x} dy ) + i ( \frac{\partial G}{\partial x} dx + \frac{\partial G}{\partial y} dy ) \qquad ( 18 )$$

There are the more crucial facts behind the (17) and (18) potentially. As a result, the total derivative of the complex function (16) depends on the real (imaginary) part of (11) function F (x, y) or G (x, y) only and never be a constant value function. One said, if changing the function of real part, the imaginary part function is also varied and determined by the real part via the equations (12) and (13). Since the functions F (x, y) and G (x, y) have to satisfy the equations (14) and (15), they are harmonic functions and then produce the frequency related elements discussed at the analytic continuation section. Moreover, the functions of real and imaginary parts are not entirely independent, referred to the Hilbert transforms in the textbooks [16, Page 296] and [18, Page 5 and Appendix One].

### Analytic Continuation

The impedance of the circuit has been discussed in this section. According to the equation (20) has shown that a PDR and NDR coupled in series in a circuit can induce significant, enlarged harmonic, sub-harmonic, super-harmonic and intermediate harmonic components which will modulate all together to present multi-band waveforms with broad bandwidth.

For each analytic function F (z) in the domain D, the Laurent series expansion of F (z) is defined as the following

$$\begin{matrix}F ( z ) = {\sum }_{n = - ∞}^{∞} {{a}_{n} ( z - {z}_{0} )}^{n} \\ = … + {{a}_{- 2} ( z - {z}_{0} )}^{- 2} + {{a}_{- 1} ( z - {z}_{0} )}^{- 1} + {a}_{0} + …\end{matrix} \qquad ( 19 )$$

where the expansion center z₀ is arbitrarily selected. Since this domain D for this analytic function F (z), any regular point imparts a center of a Laurent series [36, Page 223], i.e.,

$$F ( z ) = {\sum }_{- ∞}^{∞} {{c}_{n} ( z - {z}_{j} )}^{n}$$

where zⱼ is an arbitrary regular point in this complex analytic domain D for j=0, 1, 2, 3, . . . . For each index j, the complex variable is the product of its norm and phase,

$$z - {z}_{j} = \vert z - {z}_{j} \vert {e}^{i {θ}_{j}} \\ and \\ F ( z ) = {\sum }_{- ∞}^{∞} {c}_{n} {\vert z - {z}_{j} \vert}^{n} {e}^{i n {ω}_{j} t} \qquad ( 20 )$$

As long as a loop is formed the impedance function can be written in the form as the equation above. For each phase angle θⱼ, the corresponding frequency elements are naturally produced, say harmonic frequency ωⱼ. For different zⱼ correspond to the impedances with different values, frequencies and phases.

### Positive and Negative Differential Resistances

### PDR, NDR

More inventively, due to observing the positive and negative differential resistors properties qualitatively, we introduce the Cauchy-Riemann equations, [25, Part 1, 2], [36], [10], [34] and [3], for describing a system impedance transient behaviors and particularly in some sophisticated characteristics system parametrization by one dedicated parameter ω. Consider the impedance z in specific variables (i, v) complex form of

z=F(i,v)+jG(i,v) (21)

where i, v are current and voltage respectively. Assumed that the functions F (i, v) and G (i, v) are analytic in the specific domain. From the Cauchy-Riemann equations (12) and (13) becomes as following

$$\begin{matrix}\frac{\partial F}{\partial i} = \frac{\partial G}{\partial υ} \\ and & ( 22 ) \\ \frac{\partial F}{\partial υ} = - \frac{\partial G}{\partial i} & ( 23 )\end{matrix}$$

where in these two functions there exists one relationship based on the Hilbert transforms [16, Page 296] and [18, Page 5]. In other words, the functions F (i, v) and G (i, v) do not be obtained individually. Using the chain rule, equations (22) and (23) are further obtained

$$\begin{matrix}\frac{\partial F}{\partial ω} \frac{d ω}{d i} = \frac{\partial G}{\partial ω} \frac{d ω}{d υ} \\ and & ( 24 ) \\ \frac{\partial F}{\partial ω} \frac{d ω}{d υ} = - \frac{\partial G}{\partial ω} \frac{d ω}{d i} & ( 25 )\end{matrix}$$

where the parameter ω could be the temperature field T, magnetic field flux intensity B, optical field intensity I, in the electric field for examples, voltage v, current i, frequency ω or electrical power P, in the mechanical field for instance, magnitude of force F, and so on. Let the terms

$$\begin{matrix}\{ \begin{matrix}\frac{d ω}{d υ} > 0 \\ \frac{d ω}{d i} > 0\end{matrix} \\ or & ( 26 ) \\ \{ \begin{matrix}\frac{d ω}{d υ} < 0 \\ \frac{d ω}{d i} < 0\end{matrix} & ( 27 )\end{matrix}$$

be non-zero and the same sign. Under the same sign conditions as equation (26) or (27), from equation (24) to equation (25),

$$\begin{matrix}\frac{\partial F}{\partial ω} > 0 & ( 28 ) \\ \frac{\partial F}{\partial ω} < 0 \\ and & ( 29 ) \\ \frac{\partial F}{\partial ω} = 0 & ( 30 )\end{matrix}$$

should be held simultaneously, where (30) means a constant resistor. From the viewpoint of making a power source, the simple way to perform equations (26) and (27) is to use the pulse-width modulation (PWM) method.

After obtaining the qualitative behavoirs of equation (28) and equation (29), also we need to further respectively define the quantative behavoirs of equation (28) and equation (29). Intuitively, any complete system described by the equation (21) could be analogy to the simple-parallel oscillator as FIG. 1 or simple-series oscillator as FIG. 2 which corresponds to 2^{nd}-order differential equation respectively either as (33) or (38). Referring to [35, Vol 2, Chapter 8, 9, 10, 11, 22, 23], [15, Page 173], [4, Page 181], [20, Chapter 10] and [12, Page 951-968], as the FIG. 1, let the current iₗ and voltage v_{C} be replaced by x, y respectively.

From the Kirchhoff's Law, this simple oscillator is expressed as the form of

$$\begin{matrix}L \frac{d x}{d t} = y & ( 31 ) \\ C \frac{d y}{d t} = - x + {F}_{p} ( y ) & ( 32 )\end{matrix}$$

or in matrix form

$$[ \begin{matrix}\frac{d x}{d t} \\ \frac{d y}{d t}\end{matrix} ] = [ \begin{matrix}0 & \frac{1}{L} \\ - \frac{1}{C} & 0\end{matrix} ] [ \begin{matrix}x \\ y\end{matrix} ] + [ \begin{matrix}0 \\ \frac{{F}_{p} ( y )}{C}\end{matrix} ] \qquad ( 33 )$$

where the function Fₚ (y) represents the generalized Ohm's law and for the single variable case, Fₚ (x) is the real part function of the impedance function equation (21), the “p” in short, is a “parallel” oscillator. Furthermore, equation (33) is a Liénard system. The quality factor Qₚ is defined as

$$\begin{matrix}{Q}_{p} ≡ \frac{1}{2 {ξ}_{p}} \\ = \frac{{ω}_{pn} {f}_{p} ( y )}{L}\end{matrix} \qquad ( 34 )$$

where ξₚ is the damping ration of (33),

$${ω}_{pn} = \frac{1}{\sqrt{LC}} \qquad ( 35 )$$

is the natural frequency of (33) and

$${f}_{p} ( y ) ≡ \frac{d {F}_{p} ( y )}{d y} {\vert}_{y}$$

respectively. If taking the linear from of Fₚ (y),

Fₚ(y)=Ky

and K>0, it is a normally linear Ohm's law. Also, the states equation of a simple series oscillator in the FIG. 2 is

$$\begin{matrix}L \frac{d x}{d t} = y - {F}_{s} ( x ) & ( 36 ) \\ C \frac{d y}{d t} = - x & ( 37 )\end{matrix}$$

in the matrix form,

$$[ \begin{matrix}\frac{d x}{d t} \\ \frac{d y}{d t}\end{matrix} ] = [ \begin{matrix}0 & \frac{1}{L} \\ - \frac{1}{C} & 0\end{matrix} ] [ \begin{matrix}x \\ y\end{matrix} ] + [ \begin{matrix}- \frac{{F}_{s} ( x )}{L} \\ 0\end{matrix} ] \qquad ( 38 )$$

The i_{C}, Vₗ have to be replaced by x, y respectively. The function Fₛ (x) indicates the generalized Ohm's law and (38) is the Liénard system too. The corresponding Qₛ value is

$$\begin{matrix}{Q}_{s} = \frac{{ω}_{sn} L}{{f}_{s} ( x )} & ( 39 ) \\ where & \\ {ω}_{sn} = \frac{1}{\sqrt{LC}} & ( 40 )\end{matrix}$$

is the natural frequency of (38) and

$${f}_{s} ( x ) ≡ \frac{d {F}_{s} ( x )}{d x} {\vert}_{x}$$

respectively. Again, considering one system as the FIG. 2, let L, C be to one, then the system (38) becomes the form of

$$[ \begin{matrix}\frac{d x}{d t} \\ \frac{d y}{d t}\end{matrix} ] = [ \begin{matrix}y - {F}_{s} ( x ) \\ - x\end{matrix} ] \qquad ( 41 )$$

To obtain the equilibrium point of the system (38), setting the right hand side of the system (41) is zero

$$\{ \begin{matrix}y - {F}_{s} ( 0 ) = 0 \\ - x = 0\end{matrix}$$

where Fₛ (0) is a value of the generalized Ohm's law at zero. The gradient of (41) is

$$[ \begin{matrix}- {F}_{s}^{′} ( 0 ) & 1 \\ - 1 & 0\end{matrix} ]$$

Let the slope of the generalized Ohm's law Fₛ′ (O) be a new function as ƒₛ (0)

ƒₛ(0)=Fₛ′(0)

the correspondent eigenvalues λ_{1,2}^{s} are as

$${λ}_{1 , 2}^{s} = \frac{1}{2} [ - {f}_{s} ( 0 ) \pm \sqrt{{( {f}_{s} ( 0 ) )}^{2} - 4} ]$$

Similarly, in the simple parallel oscillator (33),

ƒₚ(0)=Fₚ′(0)

the equilibrium point of (33) is set to (Fₚ (0), 0) and the gradient of (33) is

$$[ \begin{matrix}0 & 1 \\ - 1 & {f}_{p} ( 0 )\end{matrix} ]$$

the correspondent eigenvalues λ_{1,2}^{p} are

$${λ}_{1 , 2}^{p} = \frac{1}{2} ( {f}_{p} \pm \sqrt{{( {f}_{p} ( 0 ) )}^{2} - 4} )$$

The qualitative properties of the systems (33) and (38), referred to [12] and [20], are as the following:
1. ƒₛ (0)>0, or ƒₚ (0)<0, its correspondent equilibrium point is a sink.
2. ƒₛ (0)<0, or ƒₚ (0)>0, its correspondent equilibrium point is a source.
   Thus, observing previous sink and source quite different definitions, if the slope value of impedance function Fₛ (x) or Fₚ (y), ƒₛ (x) or θₚ (y) is a positive value

Fₛ′(x)=ƒₛ(x)>0 (42)

or

F_{p′}(y)=ƒₚ(y)>0 (43)
it is the name of the positive differential resistivity or PDR. On contrary, it is a negative differential resistivity or NDR.

Fₛ′(x)=ƒₛ(x)<0 (44)

or

Fₚ′(y)=ƒₚ(y)<0 (45)
3. if ƒₛ (0)=0, or ƒₚ (0)=0, its correspondent equilibrium point is a bifurcation point, referred to [21, Page 433], [22, Page 26] and [20, Chapter 10] or fixed point, [2, Chapter 1, 3, 5, 6], or singularity point, [5], [1, Chapter 22, 23, 24].

Fₛ′(x)=ƒₛ(x)=0 (46)

or

Fₚ′(y)=ƒₚ(y)=0 (47)

### Liénard Stabilized Systems

This section has used periodical motion to check a system's stability, and also has explained the role of PDR and NDR in a stable system.

Taking the system equation (33) or equation (38) is treated as a nonlinear dynamical system analysis, we can extend these systems to be a classical result on the uniqueness of the limit cycle, referred to [1, Chapter 22, 23, 24], [22, Page 402-407], [30, Page 253-260], [20, Chapter 10, 11] and many articles [24], [17], [28], [26], [27], [14], [9], [32], [8], [13], [7], [11] for a dynamical system as the form of

$$\{ \begin{matrix}\frac{d x}{d t} = y - F ( x ) \\ \frac{d y}{d t} = - g ( x )\end{matrix} \qquad ( 48 )$$

under certain conditions on the functions F and g or its equivalent form of the nonlinear dynamics

$$\frac{{d}^{2} x}{d {t}^{2}} + f ( x ) \frac{d x}{d t} + g ( x ) = 0 \qquad ( 49 )$$

where the damping function ƒ (x) is the first derivative of impedance function F (x) with respect to the state x

ƒ(x)=F′(x) (50)

Based on the spectral decomposition theorem [21, Chapter 7], the damping function has to be a non-zero value if it is a stable system. The impedance function is a somehow specific pattern like as the FIG. 3,

y=F(x) (51)

From equation (48), equation (49) and equation (50), the impedance function F (x) is the integral of damping function ƒ (x) over one specific operated domain x>0 as

F(x)=∫₀^{x}ƒ(s)ds (52)

Under the assumptions that F, g∈C¹ (R), F and g are odd functions of x, F (0)=0, F′ (0)<0, F has single positive zero at x=a, and F increases monotonically to infinity for x≦a as x→∞, it follows that the Liénard's system equation (48) has exactly one limit cycle and it is stable. Comparing the (52) to the bifurcation point defined in the section ( ), the initial condition of the (52) is extended to an arbitrary setting as

F(x)=∫ₐ^{x}ƒ(ζ)dζ (53)

where a∈R. Also, the FIG. 4 is modified as where the dashed lines are different initial conditions. Based on above proof and carefully observing the function (50) in the FIG. 4, we conclude the critical insights of the system (48). We conclude that an adaptive-dynamic damping function F (x) with the following properties:
1. The damping function is not a constant. At the interval,

α≦a
the impedance function F (x) is

F(x)<0
The function derivative of F (x) should be

F′(x)=ƒ(x)≧0 (54)
which is a PDR as defined by (42) or (43) and

F′(x)=ƒ(x)<0 (55)
which is a NDR as defined by (44) or (45), and both hold simultaneously. Which means that the impedance function F (x) has the negative and positive slopes at the interval α≦a.
2. Following the Liénard theorem [30, Page 253-260], [20, Chapter 10, 11], [22, Chapter 8] and the correspondent theorems, corollaries and lemma, we can further conclude that one stabilized system which has at least one limit cycle, all solutions of the system (48) converge to this limit cycle even asymptotically stable periodic closed orbit. In fact, this kind of system construction can be realized a stabilized system in Poincaré sense [30, Page 253-260], [20, Chapter 10, 11], [15, Chapter 1, 2, 3, 4], [4, Chapter 3].

Furthermore, one nonlinear dynamic system is as the following form of

$$\begin{matrix}\frac{{d}^{2} x}{d {t}^{2}} + ɛ f ( x , y ) \frac{d x}{d t} + g ( x ) = 0 & ( 56 ) \\ or & \\ \{ \begin{matrix}\frac{d x}{d t} = y - ɛ F ( x , y ) \\ \frac{d y}{d t} = - g ( x )\end{matrix} & ( 57 ) \\ where & \\ f ( x , y ) & ( 58 )\end{matrix}$$

is a nonzero and nonlinear damping function,

g(x) (59)

is a nonlinear spring function, and

F(x,y) (60)

is a nonlinear impedance function also they are differentiable. If the following conditions are valid
1. there exists a>0 such that ƒ (x, y)>0 when \sqrt{x²+y²}≦a.
2. ƒ (0, 0)<0 (hence ƒ (x, y)<0 in a neighborhood of the origin).
3. g (0)=0, g (x)>0 when x>0, and g (x)<0 when x<0.
4. G (x)=∫₀^{x} g (u) du→∞ as x→∞.
   then (56) or (57) has at least one periodic solution.

### 0.1 Frequency-Shift Damping Effect

This section has used frequency shifting to re-define power generation and dissipation. This section also has revealed frequency shifting produced by a PDR and NDR coupled in series. Referring to the books [3, p 313], [31, Page 10-11], [23, Page 13] and [34, page 171-174], we assume that the function is a trigonometric Fouries series generated by a function g (t)∈ L (I), where g (t) should be bounded and the unbounded case in the book [34, page 171-174] has proved, and L (I) denotes Lebesgue-integrable on the interval I, then for each real β, we have

$${lim}_{ω \to ∞} {\int }_{I} g ( t ) {e}^{i ( ω t + β )} d t = 0 \\ where \\ {e}^{i ( ω t + β )} = cos ( ω t + β ) + isin ( ω t + β ) \qquad ( 61 )$$

the imaginary part of (61)

$${lim}_{ω -> ∞} {\int }_{I} g ( t ) sin ( ω t + β ) d t = 0 \qquad ( 62 )$$

and real part of (61)

$${lim}_{ω -> ∞} {\int }_{I} g ( t ) cos ( ω t + β ) d t = 0 \qquad ( 63 )$$

are approached to zero as taking the limit operation to infinity, ω→∞, where equation (62) or (63) is called “Riemann-Lebesgue lemma” and the parameter ω is a positive real number. If g (t) is a bounded constant and ω>0, it is naturally the (62) can be further derived into

$$\vert {\int }_{a}^{b} {e}^{i ( ω t + β )} d t \vert = \vert \frac{{e}^{i a ω} - {e}^{i b ω}}{ω} \vert \leq \frac{2}{ω}$$

where [a,b] ∈I is the boundary condition and the result also holds if on the open interval (a, b). For an arbitrary positive real number ∈>0, there exists a unit step function s (t), referred to [3, p 264], such that

∫_{I}|g(t)−s(t)|dt<∈/2

Now there is a positive real number M such that if ω≧m,

|∫_{I}s(t)e^{i(ωt+β)}dt|<∈/2 (64)

holds. Therefore, we have

$$\vert {\int }_{I} g ( t ) {e}^{i ( ω t + β )} d t \vert \leq \vert {\int }_{I} ( g ( t ) - s ( t ) ) {e}^{i ( ω t + β )} d t \vert + \vert {\int }_{I} s ( t ) {e}^{i ( ω t + β )} d t \vert \leq {\int }_{I} \vert g ( t ) - s ( t ) \vert d t + \frac{ɛ}{2} < \frac{ɛ}{2} + \frac{ɛ}{2} = ɛ \qquad ( 65 )$$

i.e., (62) or (63) is verified and hold.

According to the Riemann-Lebesgue lemma, the equation (61) or (63) and (62), as the frequency ω approaches to ∞ which means

$$ω ≫ 0 \\ then \\ {lim}_{ω -> ∞} {\int }_{I} g ( t ) {e}^{i ( ω t + β )} d t = 0 \qquad ( 66 )$$

The equation (66) is a foundation of the energy dissipation. For removing any destructive energy component, (66) tells us the truth whatever the frequencies are produced by the harmonic and subharmonic waveforms and completely “damped” out by the ultra-high frequency modulation.

Observing (66), the function g (t) is an amplitude of power which is the amplitude-frequency dependent and seen the book [22, Chapter 3, 4, 5, 6]. It means if the higher frequency ω produced, the more g (t) is attenuated. When moving the more higher frequency, the energy of (66) is the more rapidly diminished. We conclude that a large part of the power has been dissipated to the excited frequency ω fast drifting across the board of each reasonable resonant point, rather than transferred into the thermal energy (heat). After all, applying the energy to a system periodically causes the ω to be drifted continuously from low to very high frequencies for the energy absorbing and dissipating. Again removing the energy, the frequency rapidly returns to the nominal state. It is a fast recovery feature. That is, this system can be performed and quickly returned to the initial states periodically.

Consider one typical example, assumed that given the voltage

v(t)=V₀e^{j(ω}^{ᵥ}^{t+α}^{ᵥ}⁾ (67)

and current

i(t)=I₀e^{j(ω}^{ᵢ}^{t+α}^{ᵢ}⁾ (68)

the total applied power is defined as

$$\begin{matrix}P = {\int }_{0}^{T} i ( t ) υ ( t ) d t & ( 69 ) \\ = \frac{{V}_{0} {I}_{0}}{( {ω}_{υ} + {ω}_{i} )} ( {e}^{j ( {α}_{υ} + {α}_{i} + \frac{π}{2} )} ( 1 - {e}^{j ( {ω}_{υ} + {ω}_{i} ) T} ) ) & ( 70 )\end{matrix}$$

Let the frequency ω and phase angle β be as

ω=ωᵥ+ωᵢ

and

β=αᵢ+αᵥ

then equation (70) becomes into the complex form of

$$\begin{matrix}P = π ( ω , β , T ) + j Q ( ω , β , T ) & ( 71 ) \\ = \frac{{V}_{0} {I}_{0}}{ω} ( {e}^{j ( β + \frac{π}{2} )} ( 1 - {e}^{j ω T} ) ) & ( 72 )\end{matrix}$$

where real power π (ω, β, T) is

$$π ( ω , β , T ) = \frac{2 {V}_{0} {I}_{0} sin ( ω T ) cos ( 2 π - 2 β - ω T )}{ω} \qquad ( 73 )$$

and virtual power Q (ω, β, T) is

$$Q ( ω , β , T ) = \frac{2 {V}_{0} {I}_{0} sin ( ω T ) sin ( 2 π - 2 β - ω T )}{ω} \qquad ( 74 )$$

respectively. Observing (61), taking limit operation to (71), (70) or (72),

$${lim}_{ω -> ∞} \frac{{V}_{0} {I}_{0}}{ω} ( {e}^{j ( β + \frac{π}{2} )} ( 1 - {e}^{j ω T} ) ) = 0 \qquad ( 75 )$$

the electric power P is able to filter out completely no matter how they are real power (73) or virtual power (74) via performing frequency-shift or Doppler's shift operation, where ωᵥ, ωᵢ are frequencies of the voltage v (t) and current i (t), and αᵥ, αᵢ are correspondent phase angles and T is operating period respectively.

Let the real power to be zero,

$$2 π - 2 β - ω T = \frac{π}{2}$$

which means that the frequency ω is shifted to

$${ω}_{Vir} = \frac{1}{T} ( \frac{3 π}{2} - 2 β )$$

The total power (71) is converted to the maximized virtual power

$$\begin{matrix}Max ( Q ( {ω}_{Vir} , β , T ) ) = \frac{2 {V}_{0} {I}_{0} sin ( {ω}_{Vir} T )}{{ω}_{Vir}} \\ = \frac{2 {V}_{0} {I}_{0} T cos ( 2 β )}{( \frac{3 π}{2} - 2 β )}\end{matrix}$$

### Similarly,

$$2 π - 2 β - ω T = 0$$

$$or$$

$${ω}_{Re} = \frac{2}{T} ( π - β )$$

the total power (71) is totally converted to the maximized real power

$$\begin{matrix}Max ( π ( {ω}_{Re} , β , T ) ) = \frac{2 {V}_{0} {I}_{0} sin ( {ω}_{Re} T )}{{ω}_{Re}} \\ = \frac{{V}_{0} {I}_{0} T sin ( 2 β )}{( β - π )}\end{matrix}$$

In fact, moving out the frequency element ω as the (75) is power conversion between real power (73) and virtual power (74).

The impedance of a closed circuit has been discussed in the analytic continuation of the background information section. For any close loop the impedance function can be written in the complex form having real and imaginary parts shown as the equation (20), and the following three equations (26), (27) and (30) hold simultaneously. Equations (26), (27) and (30) are the intrinsic properties in any closed loop. Equations (26) and (27) are respectively defined as positive differential resistance (or PDR in short) and negative differential resistance (or NDR in short) in the present invention, and, equation (30) is defined as pure resistance. A device having PDR or NDR is respectively called a PDR device or a NDR device in the present invention. A device having pure resistance is called a pure resistor in the present invention. Revealed in the “Positive and Negative Differential Resistances” in the background information section, the PDR and NDR devices can vary with temperature field T, magnetic field such as magnetic flux intensity B, optical field such as optical field intensity I, electric field such as voltage v, current i, frequency f, electrical power P, acoustic field, mechanical field such as magnitude of force F, vibration force or any combinations of them listed above. And, the pure resistor is irrelevant to temperature field T, magnetic field such as magnetic flux intensity B, optical field such as optical field intensity I, electric field such as voltage v, current i, frequency f, electrical power P, acoustic field, mechanical field such as magnitude of force F, or vibration force.

For any closed loop, obviously, the two equations (26) and (27) can be respectively carried out by a PDR device and a NDR device, and the two simultaneously held equations (26) and (27) can be carried out by a PDR device and a NDR device electrically connected in series.

Any closed loop without the PDR and NDR devices those intrinsic properties described by the (26) and (27) can not be realized, which means that the loop's dynamic behavior is much more suppressed, concealed and difficult to be observable. In other words, a loop's dynamic behavior will be much more significantly observable if the loop has the PDR and NDR devices.

The impedance function equation (20) expressed in spectrum domain is true for any closed loop and tells that the loop in nature includes unlimited harmonic, sub-harmonic, super-harmonic, intermediate harmonic components and combinations of them in a multi-band waveforms with very broad bandwidth. But without frequency responding device in the loop some or all of the waveform components may be concealed, suppressed or in insignificantly observable mode. A loop having at least a PDR device and a NDR device electrically connected in series can have significant, more observable and enlarged harmonic, sub-harmonic, super-harmonic and intermediate harmonic components which will modulate all together to generate more significantly observable multi-band waveforms with considerably broad bandwidth.

The mathematical equation (66) has been proved always true for any g (t) in 1902. The integral part of the equation can be the form or expression of electrical power if it is interpreted into electrical domain and tells that it includes amplitude, frequency and phase. By taking frequency limit operation on the equation its integral (or summation) is approaching to zero, which can be interpreted that the electrical power is dissipated if frequency shifted to higher enough. Please note that the result after summation of the equation (66) is not function of time, which means that the dissipation of electrical power is not done by a given time internal instead the dissipation of electrical power is done by frequency shifting at an instant time. It means that the dissipation of electrical power by frequency-shifting can be done in a very effective and quick way. The “electrical power” used in here is defined as (69) in terms of current and voltage (i.e. the convolution of current and voltage). The “dissipation of electrical power” means that the electrical power in terms of current and voltage can be transformed into another energy forms such as RF, magnetic field, optical field, heat, etc, or any combination of them. For example, if frequencies in and out of CPU respectively are around 20 kHz and 3 GHz so that a lot of the electrical power will be transformed into heat under this high frequency shifting, which explains why CPU needs a strong fan.

Revealed in the frequency-shift damping effect section of the background information, a PDR device and a NDR device electrically connected in series has frequency-shift damping effect which can perform higher-frequency shifting resulting in the dissipation of electrical power. And further, as earlier revealed, the PDR, and NDR are field-interactable so that the dissipation of electrical power of a loop can be controlled by fields interactions listed above. This is a new method of the dissipation of electrical power of any closed loop by ultra-high frequency modulation revealed by the present invention. A damper can be realized by a PDR device and a NDR device electrically connected in series.

### REFERENCES

[1] Nicholas Minorsky. Nonlinear oscillations. Van Nostrand, New York., http://www.alibris.com, 1962.
[2] Alberto Abbondandolo. Morse Theory for Hamiltonian Systems. CRC Press., http://www.crcpress.com/, 2000.
[3] Tom M. Apostol. Mathematical Analysis. Addison-Wesley Publishing Company., http://www.aw-bc.com/, 2nd edition, 1975.
[4] V. I. Arnold. Geometrical Methods in the Theory of Ordinary Differential Equations. Springer-Verlag., http://www.springer-ny.com/, 2nd edition, 1988.
[5] V. I. Arnold. Theory of Singularities and its Applicatoins., volume 1. American Mathematicial Society., http://www.ams.org/, 2nd edition, 1990.
[6] Donald R. Askeland. The Science and Engineering of Materials. PWS Publishers., alternate edition, 1985.
[7] J. Balakrishnan. A geometric framework for phase synchronization in coupled noisy nonlinear systems. Physical Review E, 73:036206, 2006.
[8] Timoteo Carletti and Gabriele Villari. A note on existence and uniqueness of limit cycles for li'enard systems, 2003.
[9] V. K. Chandrasekar, M. Senthilvelan, and M. Lakshmanan. An unusual li'enard type nonlinear oscillator with properties of a linear harmonic oscillator, 2004.
[10] E. T. Copson. An introduction to the theory of functions of a complex variable. Oxford University Press., http://www.amazon.com/, 4th edition, 1948.
[11] M. C. Cross, A. Zumdieck, Ron Lifshitz, and J. L. Rogers. Synchronization by nonlinear frequency pulling. Physical Review Letters, 93:224101, 2004.
[12] R. Wong F. Cuker. The Collected Papers of Stephen Smale., volume 3. Singapore University Press., http://www.worldscibooks.com/mathematics, 2000.
[13] H. Giacomini and S. Neukirch. On the number of limit cycles of the lienard equation, 1997.
[14] Jaume Gine and Maite Grau. A note on “relaxation oscillators with exact limit cycles”, 2005.
[15] John Guckenheimer and Philip Holmes. Nonlinear Oscillations, Dynamical Systems, and Bifurcations of Vector Fields. Springer-Verlag., http://www.springer-ny.com/, 1997.
[16] Ernest A. Guillemin, editor. Synthesis of Passive Networks: Theory and Methods Appropriate to the Realization and Approximation Problems. John Wiley and Sons., 1957.
[17] Edward H. Hellen and Matthew J. Lanctot. Nonlinear damping of the lc circuit using anti-parallel diodes, 2006.
[18] Arthur R. Von Hippel. Dielectrics and Waves. A John Wiley & Sun, Inc., http://www.wiley.com, 1954.
[19] Arthur Von Hippel. Dielectric Materials and Applications. Artech House Publishers., http://www.artechhouse.com, 1995.
[20] Morris W. Hirsh and Stephen Smale. Differential Equations, Dynamical Systems and Linear Algebra. Academic Press., http://www.academicpress.com/, 1974.
[21] Thomas J. R. Hughes. Jerrold E. Marsden. Mathematical Foundations of Elasticity. Prentice-Hall, Inc., http://www.doverpublications.com/, 1984.
[22] D. W. Jordan and Peter Smith. Nonlinear Ordinary Differential Equations. Oxford University Press., http://www.oup.co.uk/academic/, 3rd edition, 1999.
[23] Yitzhak Katznelson. An Introduction to Harmonic Analysis. Cambridge University Press, http://www.amazon.com/, 2nd edition, 1968.
[24] Alexandra S. Landsman and Ira B. Schwartz. Predictions of ultra-harmonic oscillations in coupled arrays of limit cycle oscillators, 2006.
[25] Serge Lang. Complex Analysis. Springer-Verlag., http://www.springer.de/phy/books/ssp, 4th edition, 1999.
[26] Jose-Luis Lopez and Ricardo Lopez-Ruiz. The limit cycles of lienard equations in the strongly non-linear regime, 2002.
[27] Jose-Luis Lopez and Ricardo Lopez-Ruiz. Approximating the amplitude and form of limit cycles in the weakly non-linear regime of lienard systems, 2006.
[28] Jose-Luis Lopez and Ricardo Lopez-Ruiz. The limit cycles of lienard equations in the weakly nonlinear regime, 2006.
[29] A. J. Moulson and J. M. Herbert. Electroceramics: Materials, Properties, Applications. Wiley and Sun Ltd., http://www3.wileye.com, 2nd edition, 2003.
[30] Lawrence Perko. Differential Equations and Dynamical Systems. Springer-Verlag, New York, Inc., http://www.springer-ny.com, 3rd edition, 2000.
[31] Michael Reed and Barry Simon. Methods of Modern Mathematical Physics: Fourier Analysis, Self-Adjointness., volume 2. Academic Press., http://www.academicpress.com, 1975.
[32] Ali Taghavi. On periodic solutions of lienard equations, 2004.
[33] Yang Wang. Modeling of Ultracapacitor Short-term and Long-term Dynamic Behavior: Based on Dynamic Current Profile. VDM Verlag, http://www.purestockx.com/, 2009.
[34] E. T. Whittaker and G. N. Watson. A Course of Modern Analysis. Cambridge Mathematical Library., http://www.cambridge.org, 4th edition, 1927.
[35] Matthew Sands. WRichard P. Feynman, Robert B. Leighton. Feynman Lectures On Physics: The Complete And Definitive Issue., volume 3. Addison Wesley Publishing Company., http://www.aw-bc.com, 2nd edition, 1964.
[36] A. David Wunsch. Complex Variables with Applications. Addison-Wesley Publishing Company Inc., http://www.aw-bc.com/, 1983.

### SUMMARY OF THE INVENTION

It's a first objective to provide an electrochemical device built with ion and electron donors to increase its rate and amount of the chemical reactions resulting in larger output.

It's a second objective to provide a metal-air fuel cell built with ion and electron donors to increase its rate and amount of the chemical reactions resulting in larger output.

It's a third objective to provide a Zinc-air fuel cell built with ion and electron donors to increase its rate and amount of the chemical reactions resulting in larger output.

It's a fourth objective to introduce an ion-release device “polyhydroxyfullerols C₆₀(OH)ₙ” into the ion donor of the electrochemical device including the metal-air fuel cell and the Zinc-air fuel cell.

It's a fifth objective to provide a photoelectric conversion device with tremendous photo-electric conversion rate.

It's a sixth objective to provide a power generator, an power amplifier, a RF amplifier, a detector or a charger.

It's a seventh objective to provide an inventive burning assembly by using the inventive electrochemical device.

It's a eighth objective to provide a new capacitor with larger capacitance by building electrical fields between the separator and the electrodes.

### BRIEF DESCRIPTION OF THE DRAWINGS

FIG. 1 has shown a parallel oscillator;

FIG. 2 has shown a serial oscillator;

FIG. 3 has shown the function F(x) and a trajectory Γ of Liénard system;

FIG. 4 has shown the impedance function F(x) is independent of the initial condition setting;

FIG. 6a has shown the structure of a typical electrochemical device;

FIG. 6b is the front view of the electrochemical device shown in FIG. 6a;

FIG. 6c has shown a sealed electrochemical device;

FIG. 6d has shown a non-sealed electrochemical device;

FIG. 6e has shown a metal-air fuel cell in front cross-section view with an ion donor and an electron donor;

FIG. 6f has shown a metal-air fuel cell in front cross-section view with an ion donor;

FIG. 6g has shown a metal-air fuel cell in front view with a frequency modulated high voltage discharge circuit;

FIG. 7 has shown a metal-air fuel cell in front cross-section view built with a photoelectric conversion device;

FIG. 8 has shown an inventive burning assembly;

FIG. 9a has shown an electrochemical device wirelessly affected by an electron exciter;

FIG. 9b has shown an ion and electron donors realized by a frequency modulated high voltage discharge circuit;

FIG. 9c has shown a media device wirelessly affected by an electron exciter and the media device is electrically connected to the electrolyte of an electrochemical device;

FIG. 9d has shown a media device is electrically connected to an electron exciter and the electrolyte of an electrochemical device;

FIG. 9e has shown that an electron and ion exciters are nuclear waste;

FIG. 9f has shown a frequency modulated high voltage discharge circuit formed with a container of an electrochemical device;

FIG. 9g has shown a media device electrically connected to the electrolyte of an electrochemical device and a frequency modulated high voltage discharge circuit;

FIG. 9h has shown a plurality of high voltage discharge needles based on the embodiment of FIG. 9g;

FIG. 10a has shown a typical frequency modulated high voltage discharge circuit with an open discharge gap; and

FIG. 10b has shown an ion-release device is disposed by the open discharge gap of the frequency modulated high voltage discharge circuit of FIG. 10a and electrons jumping over the open discharge gap will strike the ion-release device to release ions.

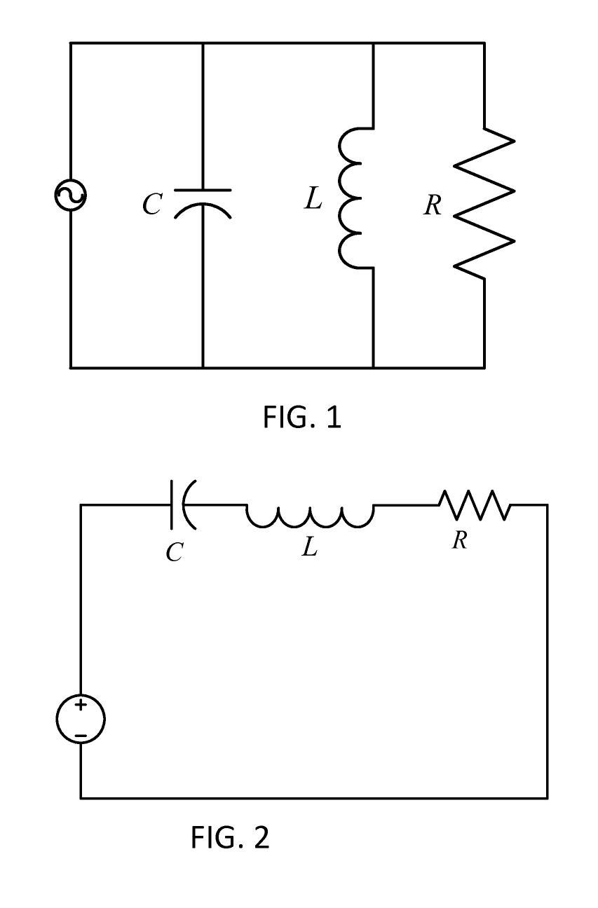

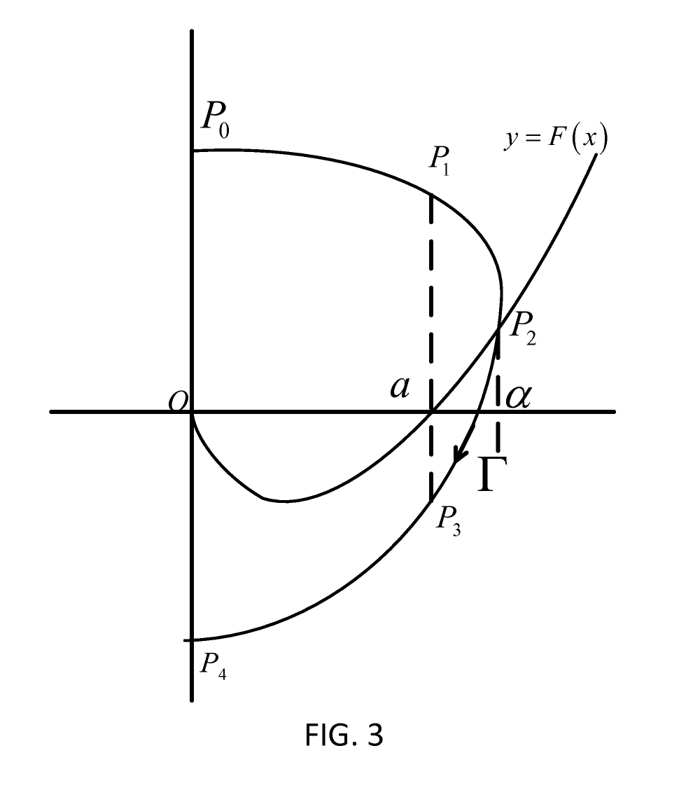

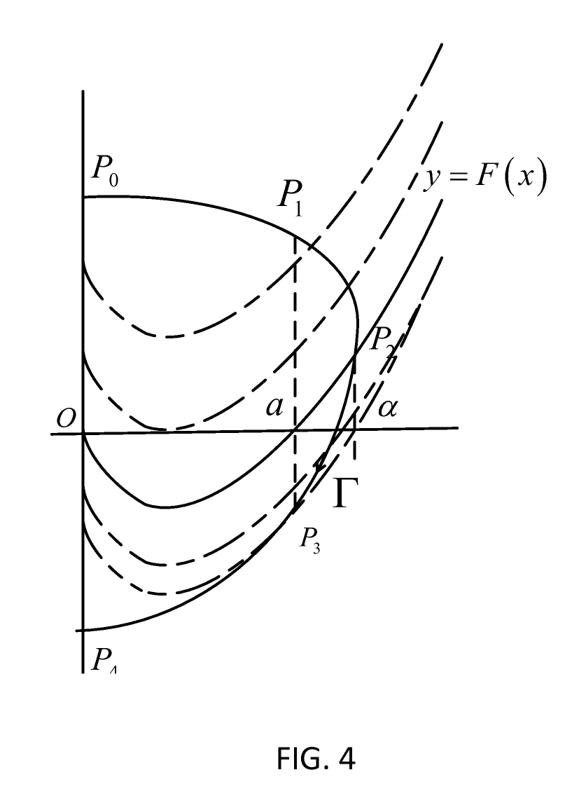

### DETAILED DESCRIPTION

An electro-chemical conversion device (or simply “electrochemical device” in short) uses chemical reactions to produce electricity or uses electricity to produce chemical reactions. Most electrochemical devices have a well-known four-component design. There is an anode electrode, a cathode electrode, a separator and an electrolyte. If the anode electrode and the cathode electrode can be safely separated the separator may not be needed. It has been known that oxidation reaction occurs at the anode electrode and reduction reaction occurs at the cathode electrode.

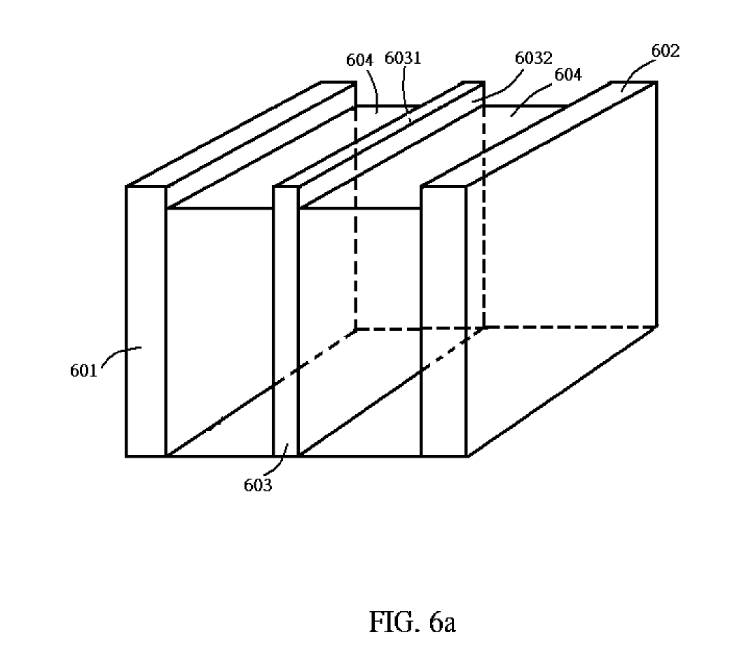

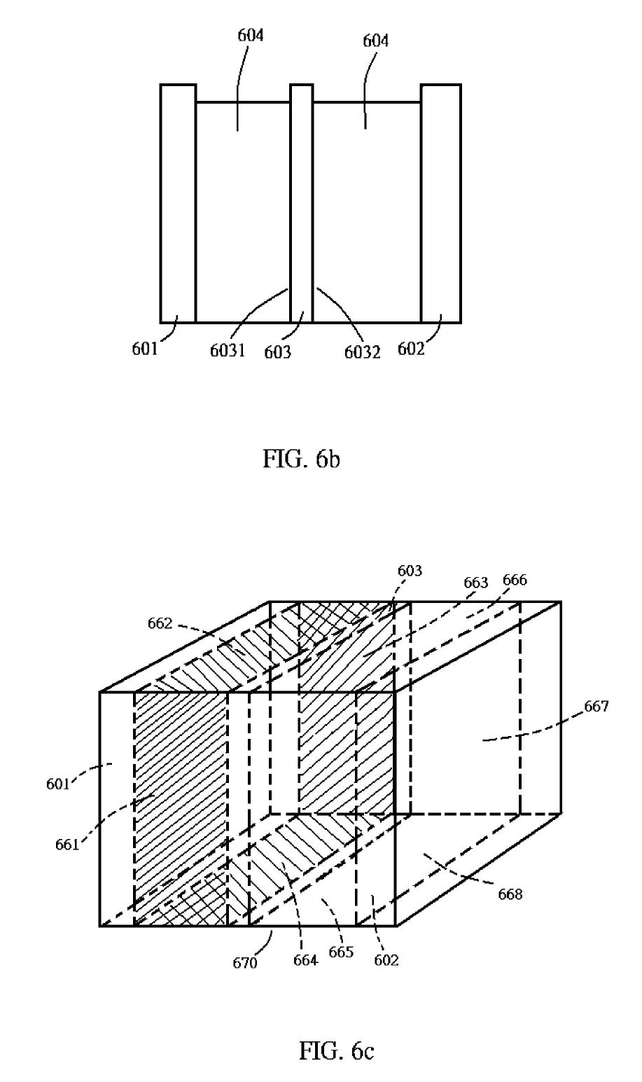

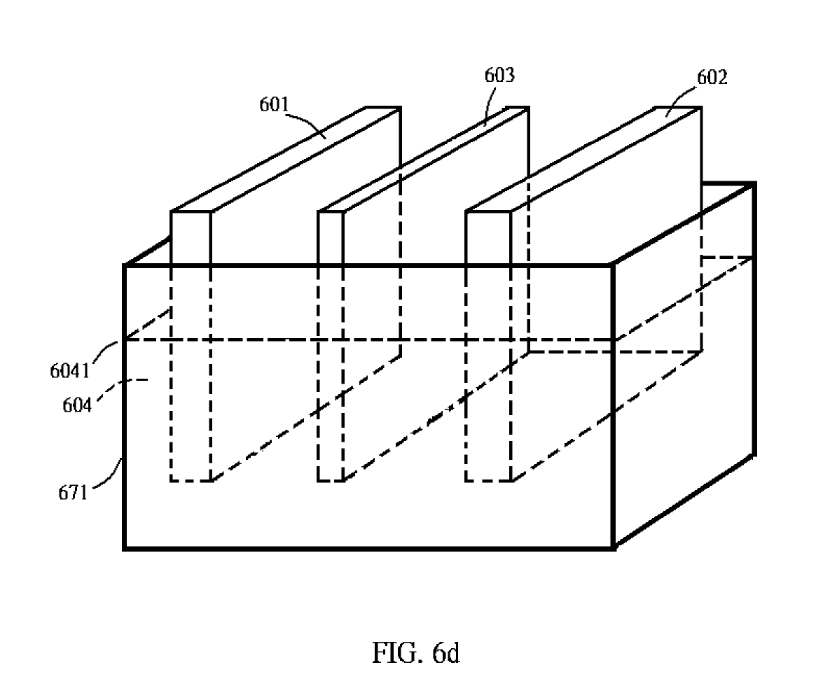

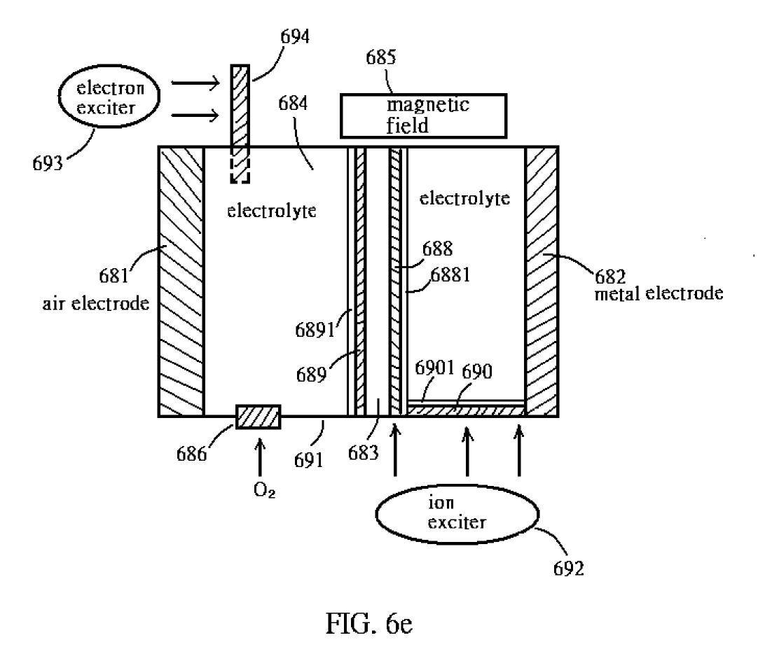

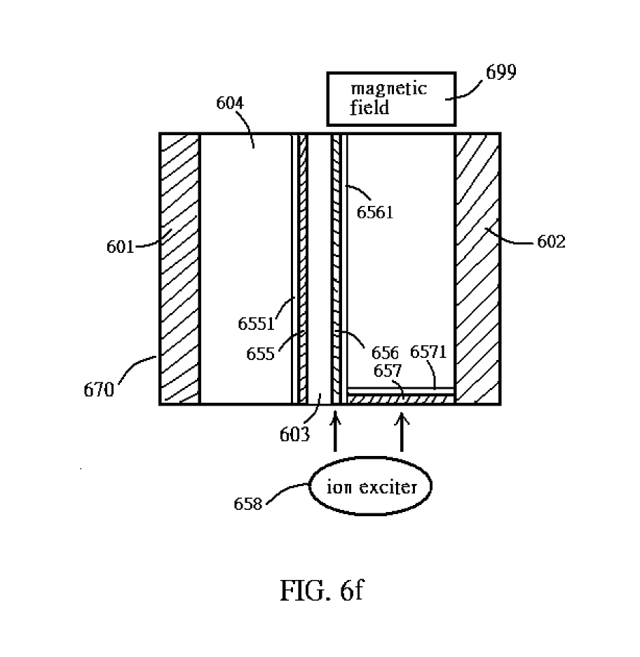

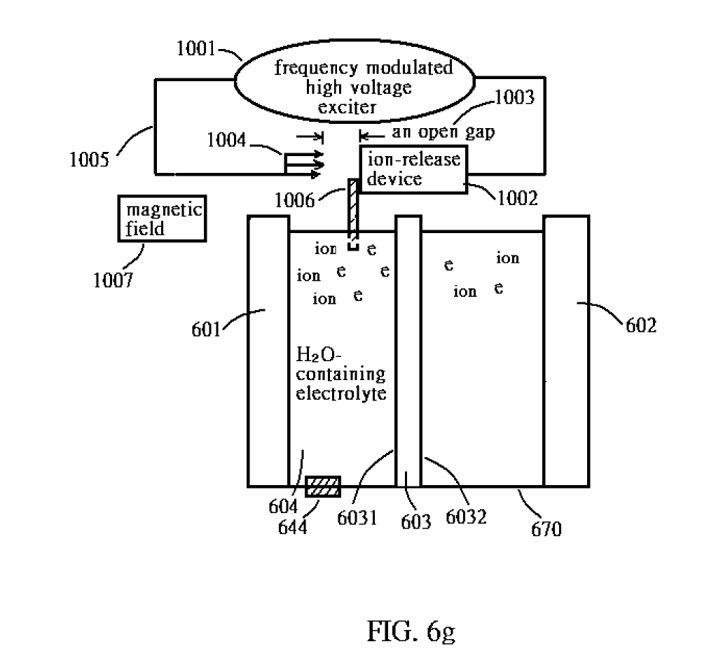

FIG. 6a has shown a typical electrochemical device. FIG. 6a has shown an anode electrode 601, a cathode electrode 602, a separator 603 disposed between the anode electrode 601 and cathode electrode 602, and an electrolyte 604 for electrical conduction between the anode electrode 601 and the cathode electrode 602.

FIG. 6b is the front view of the electrochemical device shown in FIG. 6a. For the purpose of convenience, a surface 6031 of a side of the separator 603 facing the anode electrode 601 is called “a first surface” of the separator 603 and a surface 6032 of a side of the separator 603 facing the cathode electrode 602 is called “a second surface” of the separator 603. An electrochemical device can be sealed in a container as shown in FIG. 6c or contained in a non-sealed container as shown in FIG. 6d. FIG. 6c has shown that a container 670 seals an anode electrode 601, a cathode electrode 602, a separator 603 and an electrolyte 604. FIG. 6d has shown that a container 671 contains an anode electrode 601, a cathode electrode 602, a separator 603 and an electrolyte 604. A number marked as 6041 indicates the electrolyte 604 level in the container 671.

FIG. 6c has shown four inner surfaces 661, 662, 663 and 664 of the container 670, which are marked by shaded areas, between the separator 603 and the anode electrode 601 side and there are the other four inner surfaces 665, 666, 667 and 668 of the container 670, which are not marked by shaded areas for easy reading of the drawing, between the separator 603 and the cathode electrode 602 side.

Before going further, an ion donor, an electron donor and an electron acceptor will be defined in advance. Ionization can be obtained by a physical mechanism or a chemical reaction. For example, the polyhydroxyfullerols C₆₀(OH)ₙ will release a cloud of OH⁻ ions when the polyhydroxyfullerols C₆₀(OH)ₙ are affected by an electrical field. Obviously, the OH⁻ ions released from the polyhydroxyfullerols C₆₀(OH)ₙ by the electrical field are the result of a physical mechanism not the result of a chemical reaction. An ionization obtained by a physical mechanism can be called “physical ionization” in the present invention.

An “ion donor” provides ions needed by the chemical reactions in an electrochemical device and the ions provided by the ion donor are by a physical ionization.

For example, an embodiment, an ion donor includes an exciter and an ion-release device affected by the exciter to release ions by a physical ionization. The exciter and the ion-release device are not limited. The connection between the exciter and the ion-release device is not limited, for example, the exciter and the ion-release device can be a electrically wired or wireless connection. For the purpose of convenience, the exciter of the ion donor can be called “ion exciter” in the present invention.

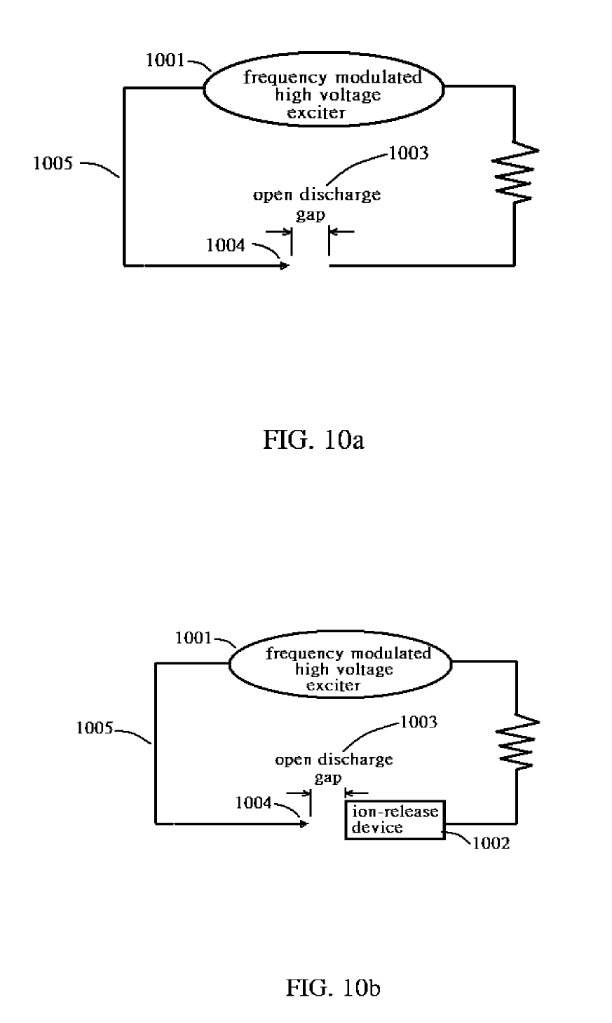

A frequency modulated high voltage discharge circuit can be employed in the ion donor. FIG. 10a has shown a frequency modulated high voltage discharge circuit comprising a frequency modulated high voltage exciter 1001, a high voltage discharge needle 1032 and an open discharge gap 1031 on the circuit. Electrons powered enough by the frequency modulated high voltage exciter 1001 can jump from the discharge needle 1032 over the open discharge gap 1031 to complete the loop. The ion-release device can be added to FIG. 10a. Based on FIG. 10a, FIG. 10b has shown that an ion-release device 1002 is disposed by the open discharge gap 1031 opposite to the discharge needle 1032. Electrons jumping over the open discharge gap 1003 will strike the ion-release device 1002 to release ions in a physical ionization method.

The high voltage exciter 1001 is frequency-modulated for being easier controlled and the frequency modulated high voltage discharge circuit of FIG. 10b has featured high voltage and very small current so that the circuit consumes less power. For example, an embodiment, the frequency modulated high voltage discharge circuit of FIG. 10b follows the Paschen's law. The ion-release device is not limited. For example, the ion-release device shown in FIG. 10b can be fullerene-containing polymers or fullerene derivatives as in the form of Cₘ(OH)ₙ or hydrogenated fullerenes CₘHₙ, where the m and n are not limited, for example, the m and n are integers and the m and n≧1. With m=60, C₆₀(OH)ₙ are very famous fullerene-containing polymers and they will be employed in the embodiments of the present invention.

It has been known that the polyhydroxyfullerols C₆₀(OH)ₙ will release a cloud of OH⁻ ions when the polyhydroxyfullerols C₆₀(OH)₇, are affected by an electrical field such as the frequency modulated high voltage exciter shown in FIG. 10b. Obviously, the OH⁻ ions released by the polyhydroxyfullerols C₆₀(OH)ₙ powered by the frequency modulated high voltage exciter are the result of a physical ionization. More about the polyhydroxyfullerols C₆₀(OH)ₙ will be discussed in the following.

The ion exciter and the ion-release device are not limited. Depending on the type of the ion-release device, the exciter can be electrical field, magnetic field, thermal field, optical field, force field such as sea wave force and wind force, acoustic field, nuclear field such as the power from nuclear waste or the combination thereof.

An “electron donor” provides electrons needed by the reduction reaction in an electrochemical device, and the electrons provided by the electron donor is the result of a physical mechanism not a result of a chemical reaction. For example, electrons flowing in a device can be induced if the impedance variation of the device is generated, obviously, the induced electrons are the result of a physical mechanism. A chemical reaction

Zn+2OH⁻→ZnO+H₂O+2e⁻

is an example of a chemical reaction to produce electrons.

An embodiment, an electron donor includes an exciter and a media device affected by the exciter. If the exciter causes the impedance variation of the media device then electrons will be induced on the media device. The exciter and the media device are not limited. The connection between the exciter and the media device is not limited, for example, the media device can be in an electrically wired or wireless connection. For the purpose of convenience, the exciter of the electron donor can be called “electron exciter” in the present invention.

It has been known that a magnetoresistance is the property of a material to change the value of its electrical resistance when an external magnetic field is applied to it. A photoresistance is the property of a material to change the value of its electrical resistance when an external optical field is applied to it. The definition can also be applied to the thermal field, force field and acoustic field. Depending on the material made of the media device the electron exciter can be an electrical field, a magnetic field, a thermal field, an optical field, a force field such as sea wave force and wind force, an acoustic field, nuclear field such as the power from nuclear waste or the combination thereof.

If a device has structure for electrons to stay then the device can be called electron acceptor in the present invention. A surface of a device has structure for electrons to stay then the surface of the device can be called “electron-accepted surface” in the present invention. For example, if a surface of a device has porous structure which can easily keep electrons to stay thereon then, obviously, the surface of the device is an electron-accepted surface.

Concepts go first. The present invention has featured that at least a significant electrical field can be built between the separator and electrodes in an electrochemical device or a capacitor and the discharge of the electrical field can deliver current. For example, if the first and second surfaces of the separator in an electrochemical device are electron-accepted surfaces then a first electrical field and a second electrical field can be respectively built between the first surface of the separator and the anode electrode and the second surface of the separator and the cathode electrode. For example, if the first and second surfaces of the separator in a capacitor are electron-accepted surfaces then the capacitance of the capacitor can largely increase.

And, the present invention has also featured that ions provided by the ion donor will be needed by the chemical reactions in the electrochemical device as a catalyst to speed the chemical reactions in the electrochemical device. As earlier revealed, an ion donor can include an exciter and an ion-release device affected by the exciter to release ions by a physical ionization, and the connection between the exciter and the ion-release device is not limited, for example, the exciter and the ion-release device can be an electrically wired or wireless connection. If the exciter is controllable then the rate of the ions provided by the ion donor is controllable. For example, the exciter can be a frequency modulated electrical field whose frequency can be controllable.

Further, the present invention has further featured that electrons provided by the electron donor will be needed by the reduction reaction in the electrochemical device as a catalyst to speed the reduction reaction in the electrochemical device. As earlier revealed, an electron donor can include an exciter and a media device affected by the exciter to induce electrons, and the connection between the exciter and the media device is not limited, for example, the exciter and the media device can be in a wired or wireless connection. If the exciter is controllable then the rate of the electrons provided by the electron donor is controllable. For example, the exciter can be a frequency modulated electrical field whose frequency can be controllable.

And furthermore, if an electrochemical device comprises a PDR device and a NDR device electrically connected in series then the frequency response of the electrochemical device will get a lot improved as revealed in the background information section.

An electrochemical device or a capacitor in front view based on FIG. 6b, if at least a portion of the separator 603 is an electron acceptor or if at least a portion of the first surface 6031 and/or the second surface 6032 of the separator 603 are electron-accepted surfaces then a significant electrical field can be built between the separator and each electrode. For example, if both the first surface 6031 and the second surface 6032 of the separator 603 are electron-accepted surfaces then a first electrical field built between the anode electrode and the separator as well as a second electrical field built between the cathode electrode and the separator can be obtained.

If at least a portion of a container containing the electrochemical device is an electron acceptor or/and if at least a portion of the inner surface of the container is an electron-accepted surface then the built-in electrical fields formed by the separator and electrodes can be further strengthened because the effective area forming the electrical fields increases. The built-in electrical field can be charged or discharged if the electrochemical device or the capacitor is in a close loop with an external circuit. The electrical field built in the electrochemical device shown in FIG. 6b can be viewed as a physical mechanism other than the chemical reaction to deliver current. If a capacitor with built-in electrical field then the capacitor has featured its increasing capacitance.

As earlier revealed, an ion donor can include an ion exciter and an ion-release device affected by the ion exciter to release ions, and, the ion exciter and the ion-release device can be an electrically wired or wireless connection. For example, an embodiment, the ion exciter can be a RF signal and the ion-release device is affected by the RF signal to release ions. An embodiment of the ion donor “the frequency modulated high voltage discharge circuit” shown in FIG. 10b, the frequency modulated high voltage exciter 1001 jumps electrons from the discharge needle 1004 over the open discharge gap to strike the ion-release device 1002 to release ions.

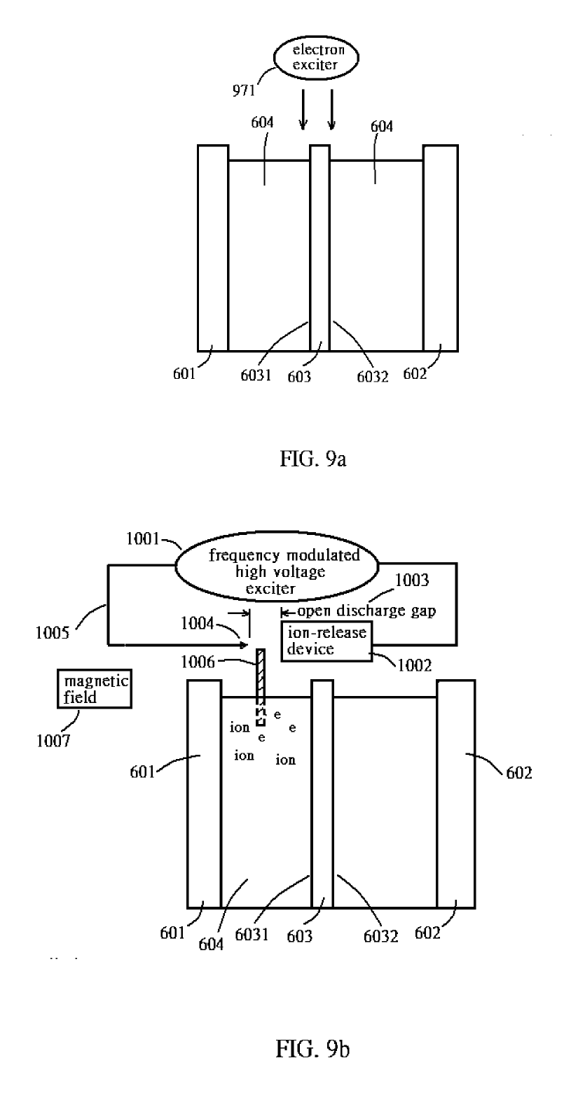

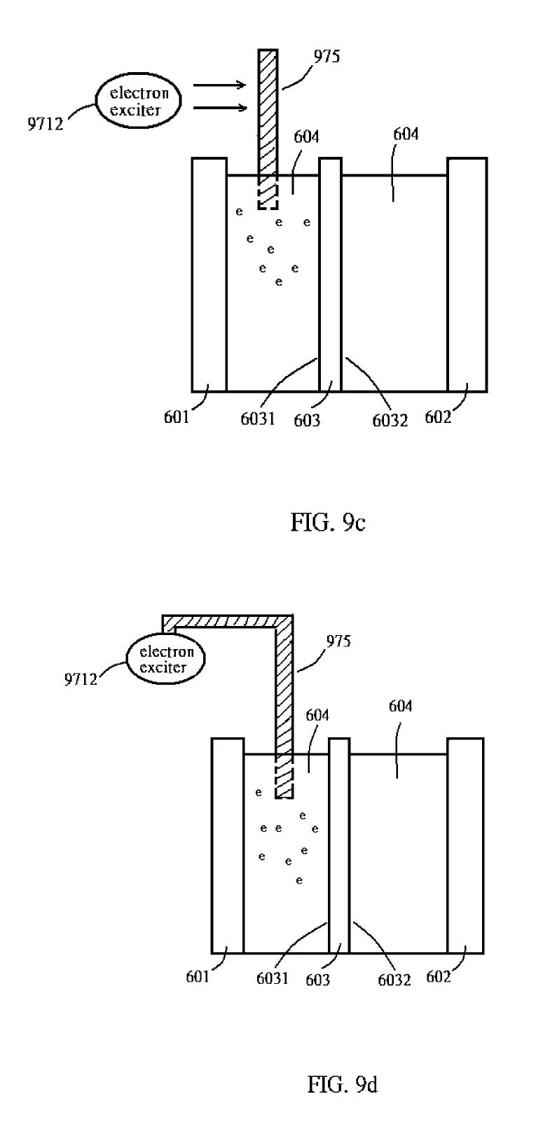

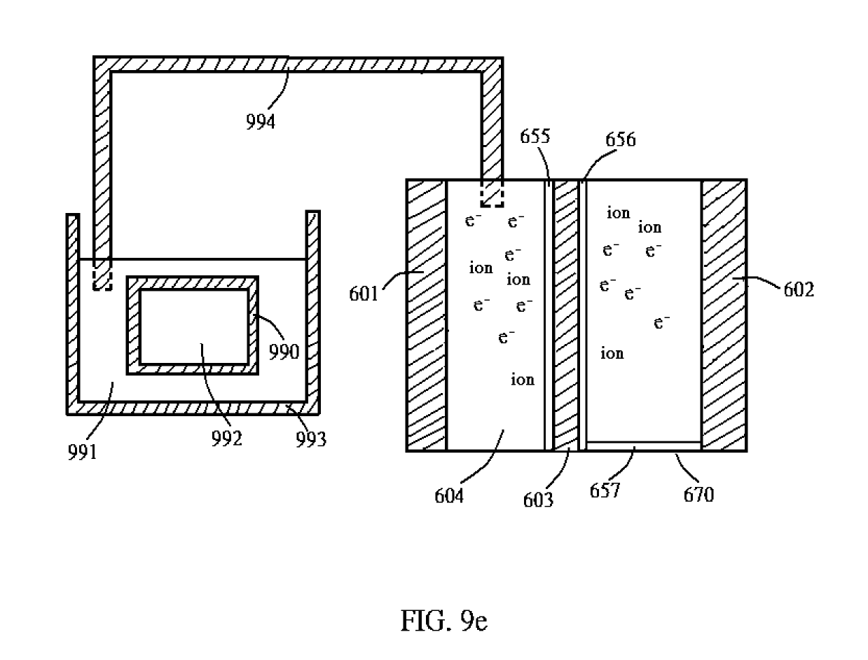

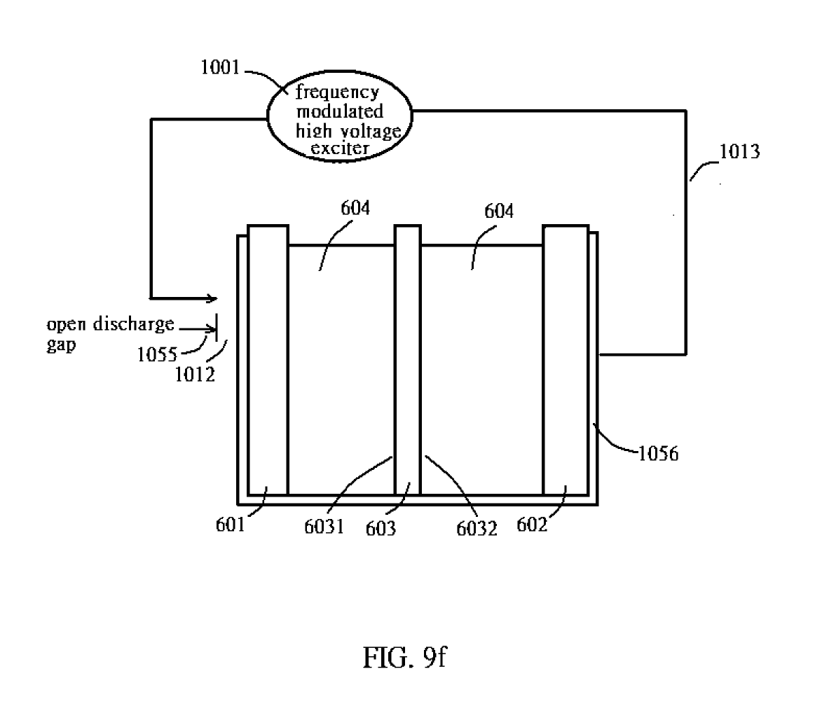

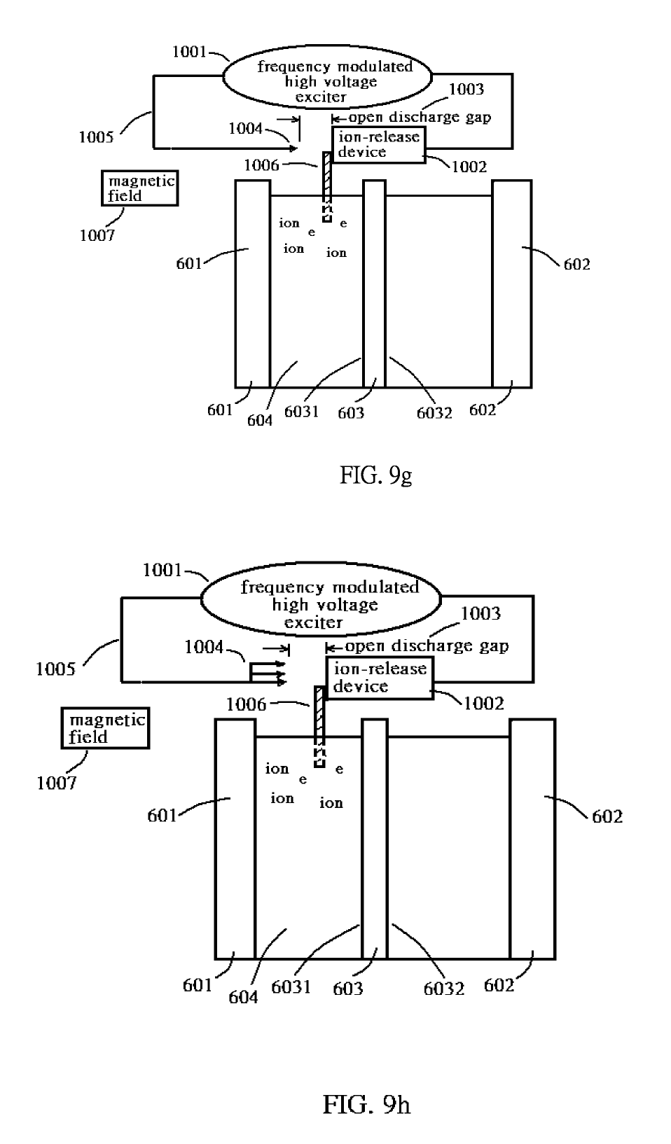

FIG. 9b has shown that the ion donor “the frequency modulated high voltage discharge circuit” shown in FIG. 10b neighbors the electrochemical device based on FIG. 6b. The electrons jumping over the open gap 1003 will strike ion-release device 1002 to release ions from the ion-release device 1002. A neighboring magnetic field 1007 is helpful to accelerate the released ions into the electrochemical device.

If the ion-release device has an area then a plurality of the high voltage discharge needles may be needed to act on multiple points on the ion-release device to increase ion releasing rate. FIG. 9h has shown three high voltage discharge needles for discharging electrons. The life cycle of ion is very short so that the released ions should be as close as to a location where chemical reaction can easily get them and a neighboring magnetic field is helpful to accelerate the released ions to an expective distance and orientation.

Ions can go through air, go through the container of an electrochemical device and migrate in the electrolyte of the electrochemical device so that the ion-release device can be disposed outside or inside the electrochemical device. The ion-release devices shown in FIGS. 9b, 9g and 9h are disposed outside the electrochemical device.

Because the same polarity repels with each other, the container can be made of a material with a same polarity with the released ions to confine the released ions in the container against fleeing out of the container. For example, if negative ions are inside the container made of negative-polarity material then the ions will be more confined in the container against fleeing out of the container.

At least a portion of the anode electrode 601, the cathode electrode 602, the separator 603, the electrolyte 604, the container 670 or the combination thereof can be made of the ion-release device, at least a portion of a surface of the anode electrode 601, the cathode electrode 602, the separator 603, the container 670 or the combination thereon can be coated by the ion-release device, or the ion-release device can be connected to the anode electrode 601, the cathode electrode 602, the separator 603, the electrolyte 604, the container 670 or the combination thereof.

The exciter is not limited, as earlier revealed, depending on the material made of the ion-release device the exciter can be an electrical field, a magnetic field, a thermal field, an optical field, a force field such as sea wave force and wind force, an acoustic field, a nuclear field such as the power from nuclear waste or the combination thereof. If ions provided by the ion donor are needed by the chemical reactions in the electrochemical device then the chemical reactions will speed up resulting in increasing output current. The exciter affecting the ion-release device can be controllable so that the rate of the ions released by the ion-release device are controllable resulting in the controllability of the chemical reactions and output current.

If the ion-release device is water soluble and has chance to contact the water-containing electrolyte then a water isolator is needed to isolate the ion-release device against dissolving into the water-containing electrolyte but still allow the ions released by the ion-release device to go through the water isolator. If the ion-release device is not water soluble or the electrolyte contains no water then the water isolator is not needed.

FIG. 6f has shown the electrochemical device of FIG. 6b in front cross-section view. FIG. 6f has shown the first surface and the second surface of the separator 603 as well as a portion of the inner surface of the container 670 are respectively coated by a first ion-release device 655, a second ion-release device 656 and a third ion-release device 657. If the three ion-release devices are water soluble and the electrolyte contains water the first ion-release device 655, second ion-release device 656 and third ion-release device 657 are respectively coated by a first water isolator 6551, a second water isolator 6561 and a third water isolator 6571 for isolating the three ion-release devices 655, 656 and 657 from dissolving into the water-containing electrolyte but allowing the released ions to go through the three water isolators 6551, 6561 and 6571. If the ion-release devices are not water soluble or the electrolyte contains no water then the water isolators are not needed.

FIG. 6f has shown an ion exciter 658 wirelessly exciting the ion-release devices 655, 656 and 657 and a magnetic field 699 for accelerating the released ions to an expective distance and orientation. The life cycle of ions is very short so that the released ions should be as close as to a location where chemical reaction can easily get them.

As revealed earlier above, an electron donor can include an electron exciter and a media device affected by the electron exciter to induce electrons which are needed by the reduction reaction in the electrochemical device, and, the electron exciter and the media device can be in a wired or wireless connection. Based on the electrochemical device of FIG. 6b, FIG. 9a has shown that the media device powered by an exciter 971 can be the anode electrode 601, the cathode electrode 602, the electrolyte 604, the separator 603, the container 670 or the combination of thereof. FIG. 9b has shown a media device 1006 is electrically connected to the electrolyte 604 and neighbors the open gap 1003 to capture at least a portion of electrons jumping over the open gap 1003. The electrons will be driven by the neighboring magnetic field 1007 to a location where the reduction reaction can easily get them. FIG. 9g has shown the media device 1006 is electrically connected to both the ion-release device 1002 and the electrolyte 604. Based on FIG. 9g, FIG. 9h has shown a plurality of the high voltage discharge needles driven by the frequency modulated high voltage exciter 1001 to discharge electrons. FIGS. 9b, 9g and 9h have shown that the ion exciter is the electron exciter. A neighboring magnetic field 1007 shown in FIGS. 9b, 9g and 9h is helpful to drive the electrons into the electrochemical device.

An embodiment, FIG. 9f has shown a container 1056 contains the electrochemical device of FIG. 6b and the frequency modulated high voltage discharge circuit of FIG. 10a electrically connecting the container 670. An open discharge gap 1012 is formed by a high voltage discharge needle 1055 and the container 1056. Electrons jump the gap 1012 to the container 670 and into the electrolyte 604 finally.

Based on FIG. 6b, FIG. 9c has shown a media device 975 electrically connecting to the electrolyte 604 and wirelessly affected by an electron exciter 9712. Electrons are induced on the media device 975 and conducted to the electrolyte 604. Based on FIG. 6b, FIG. 9d has shown the exciter 9712 and the media device 975 are in electrically wired connection. Again, as revealed before above, depending the material made of the media device the exciter can be an electrical field, a magnetic field, a thermal field, an optical field, a force field such as sea wave force and wind force, an acoustic field, nuclear field such as the power from nuclear waste or the combination thereof.

For example, an embodiment based on FIG. 9c, if the electron exciter 9712 is a RF signal the media device 975 can be viewed as an antenna to receive the RF signal so that the quality of the media device 975 such as its bandwidth and sensitivity Q is important.

Another embodiment, based on FIG. 9c, the electron exciter 9712 of the electron donor can be an incident light (optical field) and the media device 975 of the electron donor affected by the incident light can be a photoelectric conversion device such as solarcell device to convert the incident light into electricity (electrons). The incident light can be viewed as an input and an amplified power can be taken at the anode electrode and the cathode electrode so that the inventive electrochemical device can be viewed as a photoelectric conversion device such with tremendous photo-electric conversion rate.

An embodiment based on the electrochemical device of FIG. 6f and based on the electron exciter 9712 and the media device 975 of the electron donor of FIG. 9d, the electron exciter and the ion exciter can be nuclear waste. FIG. 9e has shown a nuclear waste 992 sealed in a first container 990 to be cooled down in an conductive water 991 such as sea water which is contained by a second container 993. A media device 994 electrically connects the conductive water 991 and the electrolyte 604 of the electrochemical device. The energy from the nuclear waste 992 functions as the electron exciter and the ion exciter to induce electrons and release ions.

The ion donor and electron donor can play a role as a catalyst to increase the rate and the amount of the chemical reactions in the electrochemical device resulting in larger output. The media device of the electron donor and/or the ion-release device of the ion donor can be viewed as an input terminal to receive an input and an amplified power can be taken at the anode electrode and cathode electrode so that an electrochemical device with ion and electron donors can be viewed as a power generator, an amplifier, a detector or charger. The electrochemical device with ion and electron donors allows the electrical field, magnetic field, thermal field, optical field, force field, nuclear field, acoustic field or the combination of thereof to get into it. The induced electrons should be provided as close as to a location where the reduction reaction in the electrochemical device can easily get them.

Materials respectively made of the anode electrode, cathode electrode, separator, electrolyte and container in the electrochemical device are not limited. The geometric shape of the anode electrode, cathode electrode, separator and container in the power assembly are not limited although the rectangular type is used in the embodiments.

The ion-release device is not limited. For example, the ion-release device can be fullerene-containing polymers or fullerene derivatives as in the form of Cₘ(OH)ₙ or hydrogenated fullerenes CₘHₙ, where the m and n are not limited, for example, the m and n are integers and the m and n≧1. With m=60, C₆₀(OH)ₙ are very famous fullerene-containing polymers and they will be employed in the embodiments of the present invention. Here following a brief introduction to fullerene is found in wikipedia “A fullerene is any molecule composed entirely of carbon, in the form of a hollow sphere, ellipsoid, or tube. Spherical fullerens are also called buckyballs, and cylindrical ones are called carbon nanotubes or buckytubes. Fullerenes are similar in structure to graphite, which is composed of stacked graphene sheets of linked hexagonal rings; but they may also contain pentagonal (or sometimes heptagonal) rings.”

One of very famous fullerenes is C₆₀ discovered in 1985. The fullerene C₆₀ has porous structure so that it is a good electron acceptor. Some fullerene-containing polymers or fullerene derivatives as in the form of Cₘ(OH)ₙ or hydrogenated fullerenes CₘHₙ have been successfully fabricated. The fullerene-containing polymers or fullerene derivatives polyhydroxyfullerols C₆₀(OH)ₙ are electron acceptors and NDR devices. The water-soluble polyhydroxyfullerols C₆₀(OH)ₙ are very good in conductivity and the polyhydroxyfullerols C₆₀(OH)ₙ have characterized that a cloud of OH⁻ will be escaped from C₆₀ when the polyhydroxyfullerols C₆₀(OH)ₙ are applied by an electrical field. The polyhydroxyfullerols C₆₀(OH)ₙ can be good ion-release devices and good materials coating on the first surface and the second surface of the separator as well as the inner surface of the container of the electrochemical device.

The polyhydroxyfullerols C₆₀(OH)ₙ is water soluble so that a water isolator is needed to isolate the polyhydroxyfullerols C₆₀(OH)ₙ from dissolving into the water-containing electrolyte but allowing the released ions to go through it as revealed above.

The electrochemical device is not limited. For example, the electrochemical device can be a well-known metal-air fuel cell. The anode electrode and the cathode electrode of the electrochemical device comprise the air electrode and the metal electrode, which means that the anode electrode is the air electrode and the cathode electrode is the metal electrode or the anode electrode is the metal electrode and the cathode electrode is the air electrode. The metal electrode is not limited, for example, the metal electrode can be made of such as Zn, Au, Mn, Li, Fe or Mg.

The metal electrode of metal-air fuel cell has characterized to have oxidation reaction to produce electrons which form electrical current, and H₂O, O₂ and e⁻ (electron) are needed in the reduction reaction at the air electrode side to provide OH⁻ for the oxidation reaction of the metal electrode. For the purpose of convenience, the “metal electrode” and “air electrode” will be used in the known metal-air fuel cell in the present invention. The materials made of the metal electrode and the air electrode in the metal-air fuel cell are not limited.

An embodiment, an inventive metal-air fuel cell is shown in FIG. 6e. FIG. 6e has shown an inventive metal-air fuel cell in front cross-section view. The metal-air fuel cell shown in FIG. 6e has shown a metal electrode 682, an air electrode 681, a separator 683 for separating the metal electrode 682 and the air electrode 681, at least an O₂ air inlet 686 on a container 691 for O₂ entry into the metal-air fuel cell, a H₂O-containing electrolyte 684 for providing H₂O needed by the chemical reactions at the air electrode's 682 side, a first polyhydroxyfullerols C₆₀(OH)ₙ 689 coated on the first surface of the separator 683 for releasing OH⁻ ions, a second polyhydroxyfullerols C₆₀(OH)ₙ 688 coated on the second surface of the separator 683 for releasing OH⁻ ions, a third polyhydroxyfullerols C₆₀(OH)ₙ 690 coating on a portion of the inner surface of the container 691 for releasing OH⁻ ions, a first water isolator 6891 coating on the first polyhydroxyfullerols C₆₀(OH)ₙ 689, a second water isolator 6881 coating on the second polyhydroxyfullerols C₆₀(OH)ₙ 688, a third water isolator 6901 coating on the third polyhydroxyfullerols C₆₀(OH)ₙ 690, an exciter 692 outside the metal-air fuel cell for driving the ions off from the polyhydroxyfullerols C₆₀(OH)ₙ, a magnetic field 685 for accelerating the released ions to an expective distance and orientation, an electron exciter 693 and a media device 694 electrically connected to the electrolyte 684.

If the OH⁻ ions escaped from the polyhydroxyfullerols C₆₀(OH)ₙ have enough power to travel to a location where chemical reactions can get them then the magnetic field 685 may not be needed.

Another embodiment of a metal-air fuel cell shown in FIG. 6g is obtained by adding an air inlet 644 for O₂ entry to the embodiment of FIG. 9h. The electrolyte 604 contains water H₂O and O₂ needed by the chemical reaction at the air electrode 601. The ion-release device 1002 shown in 6g can be the polyhydroxyfullerols C₆₀(OH)ₙ to release OH⁻ needed by the metal electrode 602. The magnetic field 1007 is for accelerating the OH⁻ ions and electrons as revealed before.

The Zinc-air fuel cell is a very representative fuel cell in the metal-air fuel cell group and further detailed about the metal-air fuel cell can be easier understood by demonstrating the Zinc-air fuel cell. Before going further, chemical reactions involved in the Zinc-air fuel cell will be discussed in advance. The oxidation reaction and reduction reaction of the Zinc-air fuel cell can be respectively described by

Zn+2OH⁻→ZnO+H₂O+2e⁻

and

O₂+2H₂O+4e⁻→4OH⁻.

The reduction reaction

O₂+2H₂O+4e⁻4OH⁻

has told that the air electrode side needs O₂, H₂O and e⁻ to obtain OH⁻ ions which are needed by the Zinc electrode side to produce electrons shown by the oxidation reaction

Zn+2OH⁻→ZnO+H₂O+2e⁻.

The ion donor and the electron donor revealed in the present invention can be help to the Zinc-air fuel cell. The ion donor can provide OH⁻ needed by the oxidation reaction and the electron donor can provide electrons needed by reduction reaction so that the initiation of the Zinc-air fuel cell can be easily obtained and the rate and the amount of the chemical reactions in the Zinc-air fuel cell can a lot increase resulting in larger output. The embodiment of FIG. 6g can be applied to the Zinc-air fuel cell by assigning the metal electrode as Zinc electrode. The ion exciter 1001, the electron exciter 1001 and the magnetic field 1007 are controllable, for example, their frequencies are controllable, so that the chemical reactions of the electrochemical device can be controllable resulting in the controllability of output current.

Now the O₂, H₂O, e⁻ and OH⁻ are all ready for the inventive electrochemical device and once the e⁻ and OH⁻ are provided by the electron donor and ion donor a chain of chemical reactions rolls on to deliver considerable current as expected.

An embodiment, the media device of the electron donor can be viewed as an input terminal to receive an input signal and an amplified output can be taken at the air electrode and the metal electrode so that the inventive metal-air fuel cell can be viewed as an amplifier, a three-terminal amplifier, a power generator, a RF amplifier or a detector. A signal is input at a first terminal and an amplified power duplicating the signal is taken at a second terminal and a third terminal.

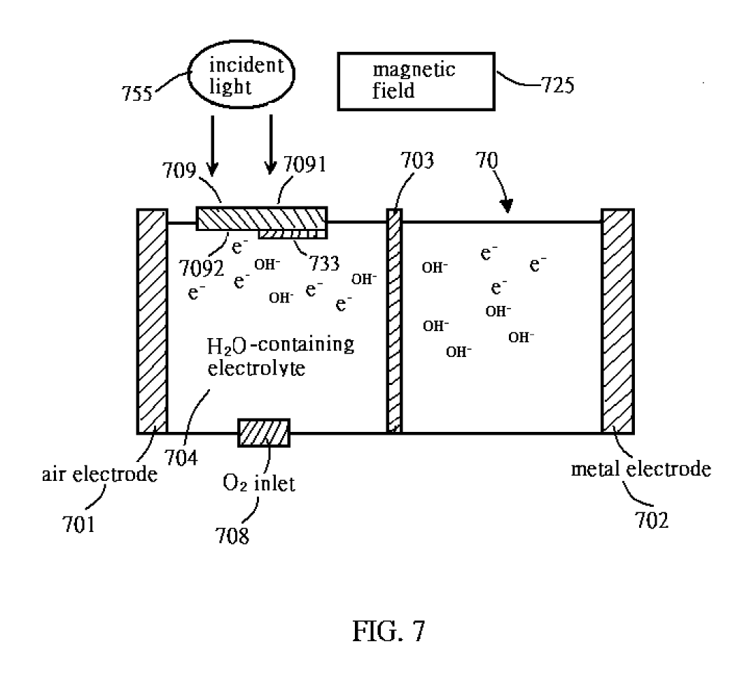

The electron exciter can be an incident light and the media device affected by the incident light can be a photoelectric conversion device such as solarcell to convert the incident light into electricity (electrons) as revealed above. FIG. 7 has shown the result. An embodiment, FIG. 7 has shown the photoelectric conversion device 709 with its first side 7091 receiving incident light 755 and a portion of its second side 7092 opposite to the first side 7091 electrically connecting to the electrolyte 704 so that electrons converted by the photoelectric conversion device 709 powered by the incident light 755 can conduct into the electrolyte 704. An ion-release device 733 powered by the incident light 755 can also be disposed on a portion of the second side 7092 of the photoelectric conversion device 709 and connected to the electrolyte 704 so that the ions released by the ion-release device 733 powered by the incident light 755 can migrate in the electrolyte 704. The ion-release device 733 can be the polyhydroxyfullerols C₆₀(OH)ₙ, and, in this case, a water isolator is needed as revealed above.

The electron donor is not limited. The electron exciter and the media device affected by the electron exciter of the electron donor are not limited. For example, the media device should have very broad bandwidth and good frequency responses. A damper realized by a PDR device and a NDR device electrically connected in series is a good media device because it has very broad bandwidth and good frequency response as revealed in the background information. And also revealed in the “Positive and Negative Differential Resistances” section in the background information, the PDR and NDR devices can vary with different energy field such as temperature field T, magnetic field such as magnetic flux intensity B, optical field such as optical field intensity I, electric field such as voltage v, current i, frequency f, electrical power P, acoustic field, mechanical field such as magnitude of force F, vibration force or the combination thereof. An our earlier invention “an antenna” including a parallel oscillator and a serial oscillator electrically connected in series is also a good media device.

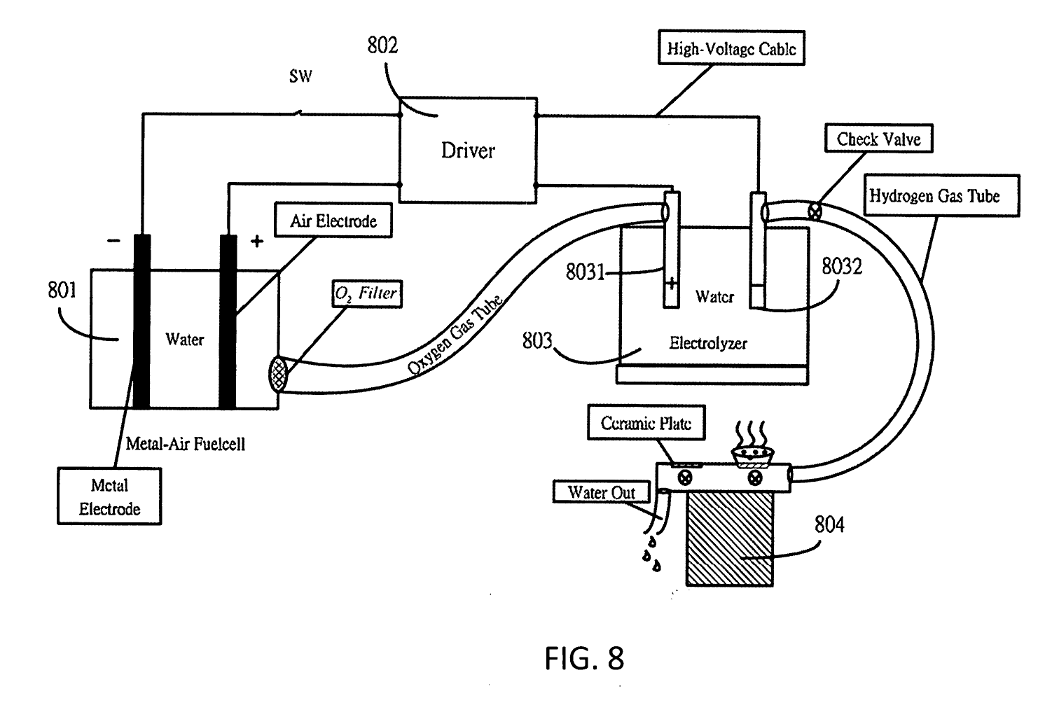

The inventive metal-air fuel cells have many applications. An embodiment shown in FIG. 8, the inventive metal-air fuel cells can be used to construct a burning assembly which can be a cooking device used in kitchen or a high-temperature burning furnace used in industry. The burning assembly comprises the metal-air fuel cell 801, a water-containing electrolyzed pool 803 having a positive electrode 8031 and a negative electrode 8032, a driver 802 for electrolyzing the water of the electrolyzed pool 803 to separate the H₂ and O₂ gases respectively at the negative and positive electrodes 8032, 8031 and a burning device 804 by burning the H₂ gas out from the electrolyzed pool 803. The O₂ gas separated from the electrolyzed pool 803 can be fed into the metal-air fuel cell 801 as O₂ source to the fuel cell.

H₂ gas is very active and very hard to be kept in a container. The inventive burning assembly has advantaged that how much the H₂ gas to be burned will be how much the H₂ gas to be generated so that the burning assembly needs no H₂ gas storage, which is safer. The rate or amount of H₂ gas generated can be controlled by the driver 802, for example, by controlling the frequency of the driver 802, so that the temperature by burning H₂ gas and burning environment such as the emergency procedure can be controlled.

The temperature of burning H₂ gas can be very high so that the inventive burning assembly is also a good burning furnace for industrial use. The inventive burning assembly needs no H₂ gas storage so that it is safer. Further, the inventive burning assembly produces H₂O and doesn't produce CO₂ and CO so that it's good for environment and safer to people. The driver 802 in the burning assembly is not limited. The electrolyzed pool 803 in the burning assembly is not limited. The burning device 804 is not limited. The metal-air fuel cell is not limited.

The electrolyte of the inventive metal-air fuel cell can be sea water so that the metal-air fuel cell can be disposed in the sea to produce electricity.

1. An electrochemical device, comprising:
an anode electrode, wherein an oxidation reaction occurs at the anode electrode;
a cathode electrode, wherein a reduction reaction occurs at the cathode electrode;
an electrolyte electrically connecting to the anode electrode and the cathode electrode; and
an ion donor for providing ions needed by the chemical reaction in the electrochemical device, wherein the ions provided by the ion donor are by a physical ionization.

2. The electrochemical device of claim 1, further comprising an electron donor for providing electrons needed by the reduction reaction, wherein the electrons provided by the electron donor are by a physical mechanism.

3. The electrochemical device of claim 1, further comprising a separator disposed between the anode electrode and the cathode electrode.

4. The electrochemical device of claim 2, further comprising a separator disposed between the anode electrode and the cathode electrode.

5. The electrochemical device of claim 2, wherein the ion donor comprises an ion exciter and an ion-release device affected by the ion exciter to release ions, and the electron donor comprises an electron exciter and a media device affected by the electron exciter to induce electrons, and the ion exciter and the electron exciter are an electrical field, a magnetic field, a thermal field, an optical field, a force field, an acoustic field, a nuclear waste field or the combination thereof.

6. The electrochemical device of claim 4, wherein the ion donor comprises an ion exciter and an ion-release device affected by the ion exciter to release ions, and the electron donor comprises an electron exciter and a media device affected by the electron exciter to induce electrons, and the ion exciter and the electron exciter are an electrical field, a magnetic field, a thermal field, an optical field, a force field, an acoustic field, a nuclear waste field or the combination thereof.

7. The electrochemical device of claim 5, further comprising a magnetic field for accelerating the ions provided by the ion donor and the electrons provided by the electron donor to a location where the chemical reaction easily gets them.

8. The electrochemical device of claim 6, further comprising a magnetic field for accelerating the ions provided by the ion donor and the electrons provided by the electron donor to a location where the chemical reaction easily gets them.

9. The electrochemical device of claim 7, wherein the ion exciter is a frequency modulated high voltage exciter and the ion-release device is a fullerene derivative as in the form of Cₘ(OH)ₙ affected by the frequency modulated high voltage exciter to release OH⁻ ions, and a frequency modulated high voltage discharge circuit is formed by the frequency modulated high voltage exciter and the fullerene derivative Cₘ(OH)ₙ electrically connected in series with each other with an open discharge gap on the frequency modulated high voltage discharge circuit, and the frequency modulated high voltage discharge circuit at a side of the open discharge gap has a high voltage discharge needle and the fullerene derivative Cₘ(OH)ₙ is connected to the frequency modulated high voltage discharge circuit at the other side of the open discharge gap, and electrons emitting from the high voltage discharge needles over the open discharge gap strike the fullerene derivative Cₘ(OH)ₙ to release OH⁻ ions, and OH⁻ ions released by the Cₘ(OH)ₙ are accelerated by the magnetic field, and the media device electrically connects the electrolyte and the fullerene derivative Cₘ(OH)ₙ, and the media device captures the electrons jumping over the open discharge gap driven by the frequency modulated high voltage exciter to conduct into the electrolyte, and the captured electrons are accelerated by the magnetic field, and the ions released by fullerene derivative Cₘ(OH)ₙ are also conducted into the electrolyte, and m and n are integers and m and n≧1.

10. The electrochemical device of claim 7, wherein the ion exciter is a frequency modulated high voltage exciter and the ion-release device is a fullerene derivative as in the form of Cₘ(OH)ₙ affected by the frequency modulated high voltage exciter to release OH⁻ ions, and a frequency modulated high voltage discharge circuit is formed by the frequency modulated high voltage exciter and the fullerene derivative Cₘ(OH)ₙ electrically connected in series with each other with an open discharge gap on the frequency modulated high voltage discharge circuit, and the frequency modulated high voltage discharge circuit at a side of the open discharge gap has a high voltage discharge needle and the fullerene derivative Cₘ(OH)ₙ is connected to the frequency modulated high voltage discharge circuit at the other side of the open discharge gap, and electrons emitting from the high voltage discharge needles over the open discharge gap strike the fullerene derivative Cₘ(OH)ₙ to release OH⁻ ions, and OH⁻ ions released by the Cₘ(OH)ₙ are accelerated by the magnetic field, and the media device electrically connects the electrolyte and the fullerene derivative Cₘ(OH)ₙ, and the media device captures the electrons jumping over the open discharge gap driven by the frequency modulated high voltage exciter to conduct into the electrolyte, and the captured electrons are accelerated by the magnetic field, and the ions released by fullerene derivative Cₘ(OH)ₙ are also conducted into the electrolyte, and m and n are integers and m and n≧1.

11. The electrochemical device of claim 9, wherein the Cₘ(OH)ₙ is C₆₀(OH)ₙ, and the media device electrically connects the electrolyte and the frequency modulated high voltage discharge circuit to conduct the electrons into the electrolyte.

12. The electrochemical device of claim 10, wherein the Cₘ(OH)ₙ is C₆₀(OH)ₙ, and the media device electrically connects the electrolyte and the frequency modulated high voltage discharge circuit to conduct the electrons into the electrolyte.

13. The electrochemical device of claim 7, wherein the ion exciter and the ion-release device are in an electrically wired or wireless connection, and the electron exciter and the media device are in an electrically wired or wireless connection.

14. The electrochemical device of claim 8, wherein the ion exciter and the ion-release device are in an electrically wired or wireless connection, and the electron exciter and the media device are in an electrically wired or wireless connection.

15. The electrochemical device of claim 11, wherein the anode electrode and the cathode comprises an air electrode and an metal electrode, and the electrolyte contains H₂O and O₂ which are needed by the chemical reaction at the air electrode.

16. The electrochemical device of claim 12, wherein the anode electrode and the cathode comprises an air electrode and an metal electrode, and the electrolyte contains H₂O and O₂ which are needed by the chemical reaction at the air electrode.

17. The electrochemical device of claim 7, wherein the electron exciter is an optical field and the media device is a photo-electric conversion device to convert the optical field into electrons, and the photoelectric conversion device electrically connects the electrolyte to conduct the electrons converted by the optical field into the electrolyte, and the ion-release device connects the electrolyte and attaches the photoelectric conversion device, and the photoelectric conversion device powered by the optical field drives the ion-release device to release ions to migrate in the electrolyte.

18. The electrochemical device of claim 7, wherein the electron exciter is an optical field and the media device is a photo-electric conversion device to convert the optical field into electrons, and the photoelectric conversion device electrically connects the electrolyte to conduct the electrons converted by the optical field into the electrolyte, and the ion-release device connects the electrolyte and attaches the photoelectric conversion device, and the photoelectric conversion device powered by the optical field drives the ion-release device to release ions to migrate in the electrolyte.

19. The electrochemical device of claim 17, wherein the anode electrode and the cathode comprises an air electrode and an metal electrode, and the electrolyte contains H₂O and O₂ which are needed by the chemical reaction at the air electrode, and the ion-release device is the fullerene derivative C₆₀(OH)ₙ, and a water isolator coats on the fullerene derivative C₆₀(OH)ₙ for isolating the fullerene derivative C₆₀(OH)ₙ against dissolving into the H₂O-containing electrolyte, and n is an integer and n≧1.

20. The electrochemical device of claim 18, wherein the anode electrode and the cathode comprises an air electrode and an metal electrode, and the electrolyte contains H₂O and O₂ which are needed by the chemical reaction at the air electrode, and the ion-release device is the fullerene derivative C₆₀(OH)ₙ, and a water isolator coats on the fullerene derivative C₆₀(OH)ₙ for isolating the fullerene derivative C₆₀(OH)ₙ against dissolving into the H₂O-containing electrolyte, and n is an integer and n≧1.

21. A capacitor, comprising:
a positive electrode;
a negative electrode;
an electrolyte electrically connecting to the positive electrode and the negative electrode; and
a separator for separating the positive electrode and the negative electrode, wherein a first electrical field is built between the positive electrode and the separator and a second electrical field is built between the negative electrode and the separator for increasing the capacitance of the capacitor.

22. A burning assembly, comprising:
an electrochemical device, comprising:
a metal electrode, wherein an oxidation reaction occurs at the anode electrode;
an air electrode, wherein a reduction reaction occurs at the cathode electrode;
an electrolyte containing H₂O needed by the chemical reactions at the air electrode side;
an ion donor for providing ions needed by chemical reactions in the electrochemical device, wherein the ions provided by the ion donor are by a physical ionization;
an electron donor for providing electrons needed by the reduction reactions, wherein the electrons provided by the electron donor are by a physical mechanism;
a magnetic field for accelerating the ions provided by the ion donor and the electrons provided by the electron donor into the electrochemical device; and
an O₂ inlet for O₂ entry into the electrolyte, wherein the O₂ is needed by the chemical reactions at the air electrode side;
an electrolyzed pool having a positive electrode and a negative electrode;
a driver powered by the electrochemical device for driving the electrolyzed pool through its the positive electrode and the negative electrode, wherein the driver drives the electrolyzed pool to separate H₂ and O₂ respectively at its negative electrode and positive electrode, and the O₂ gas is provided to the electrochemical device through the O₂ inlet, and
a burning device for burning the H₂ electrolyzed from the electrolyzed pool.

23. The burning assembly of claim 22, wherein the ion donor comprises an ion exciter and an ion-release device and the electron donor comprises an electron exciter and a media device, and the ion exciter is a frequency modulated high voltage exciter and the ion-release device is fullerene derivative C₆₀(OH)ₙ affected by the frequency modulated high voltage exciter to release OH⁻ ions, and a frequency modulated high voltage discharge circuit is formed by the frequency modulated high voltage exciter and the fullerene derivative C₆₀(OH)ₙ connected in series with each other with an open discharge gap on the frequency modulated high voltage discharge circuit, and the frequency modulated high voltage discharge circuit at a side of the open discharge gap has a plurality of high voltage discharge needles and the fullerene derivative C₆₀(OH)ₙ is located at the other side of the open discharge gap to release OH⁻ ions when electrons emitting from the high voltage discharge needles over the open discharge gap strike the fullerene derivative C₆₀(OH)ₙ, and the media device electrically connects the electrolyte and the frequency modulated high voltage discharge circuit to conduct the electrons into the electrolyte, and the n is an integer and n≧1.

24. The burning assembly of claim 22, further comprising a separator for separating the metal electrode and the air electrode.

25. The burning assembly of claim 23, further comprising a separator for separating the metal electrode and the air electrode.

26. The electrochemical device of claim 5, wherein the media device and the ion-release device are electrically connected to the electrolyte, and the electron exciter and the ion exciter respectively wirelessly affect the media device and the ion-release device.

27. The electrochemical device of claim 5, wherein the media device or the ion-release device is electrically connected to the electrolyte, and the electron exciter and the ion exciter respectively wirelessly affect the media device and the ion-release device.

28. The electrochemical device of claim 26, wherein the media device and the ion-release device receive an input and the amplified output is taken at the anode electrode and the cathode electrode.

29. The electrochemical device of claim 27, wherein the media device or the ion-release device receives an input and the amplified output is taken at the anode electrode and the cathode electrode.

30. The electrochemical device of claim 26, further comprising a container for containing the anode electrode, the cathode electrode and the electrolyte, wherein the media device is the container.

31. The electrochemical device of claim 27, further comprising a container for containing the anode electrode, the cathode electrode and the electrolyte, wherein the media device is the container.
